(19) United States
(12) Patent Application Publication
(10) Pub. No.: US 2026/0280223 A1
(43) Pub. Date: Sep. 17, 2026

(54) LIGHT-EMITTING DEVICE AND PROJECTION APPARATUS

(71) Applicant: Hisense Laser Display Co., Ltd, Qingdao City (CN)

(72) Inventors: Ke YAN, Qingdao City (CN); Zhaoshi GUO, Qingdao City (CN); Zinan ZHOU, Qingdao City (CN); Yao LU, Qingdao City (CN)

(73) Assignee: Hisense Laser Display Co., Ltd, Qingdao City (CN)

(21) Appl. No.: 19/681,253

(22) Filed: May 19, 2026

Related U.S. Application Data
(63) Continuation of application No. PCT/CN2024/099926, filed on Jun. 18, 2024.

(30) Foreign Application Priority Data
Nov. 23, 2023 (CN) 202311575066.9
Dec. 15, 2023 (CN) 202311732688.8

(51) Int. Cl. H01S 5/02253; G03B 21/20; H01S 5/02255; H01S 5/40

(52) U.S. Cl. CPC H01S 5/02253; G03B 21/2013; H01S 5/02255; H01S 5/4031; H01S 5/4087

(57) ABSTRACT

A light-emitting device and a projection apparatus are provided. The light-emitting device includes a plurality of light-emitting chips and a collimating lens. The collimating lens includes a first collimating portion and a second collimating portion. The first collimating portion is configured to: reduce a divergence angle of a laser beam exiting from the first collimating portion in a first direction to 0°, reduce a divergence angle of the laser beam exiting from the first collimating portion in a second direction, and the divergence angle of the laser beam exiting from the first collimating portion in the second direction is greater than 0°. The second collimating portion is configured to reduce a divergence angle of a laser beam exiting from the second collimating portion in the second direction to 0°.

### CROSS-REFERENCE TO RELATED APPLICATION(S)

This application is a continuation application of International Patent Application No. PCT/CN2024/099926, filed on Jun. 18, 2024, which claims priority to Chinese Patent Application No. 202311732688.8, filed on Dec. 15, 2023; and Chinese Patent Application No. 202311575066.9, filed on Nov. 23, 2023, which are incorporated herein by reference in their entirety.

### TECHNICAL FIELD

The present disclosure relates to the field of laser projection technologies, and in particular, to a light-emitting device and a projection apparatus.

### BACKGROUND

With the popularization and application of projection apparatuses, consumers have a growing demand for miniaturized projection apparatuses. To achieve miniaturization of the projection apparatuses, it is necessary to not only achieve a basic lighting function but also take into account multiple aspects such as volume, cost and optical efficiency in the design of laser source products.

### SUMMARY

In an aspect, a light-emitting device is provided. The light-emitting device includes a plurality of light-emitting chips and a collimating lens. The plurality of light-emitting chips are configured to emit laser beams. The collimating lens is located on laser-exit sides of the plurality of light-emitting chips. The collimating lens is configured to receive the laser beams from the plurality of light-emitting chips and collimate the incident laser beams. The collimating lens includes a first collimating portion and a second collimating portion. The first collimating portion is a surface of the collimating lens facing the plurality of light-emitting chips. The first collimating portion is configured to: collimate an incident laser beam in a first direction and reduce a divergence angle of the incident laser beam in a second direction, such that a divergence angle of a laser beam exiting from the first collimating portion in the first direction is reduced to 0°, a divergence angle of the laser beam exiting from the first collimating portion in the second direction is reduced, and the divergence angle of the laser beam exiting from the first collimating portion in the second direction is greater than 0°. A divergence angle of the laser beam incident on the first collimating portion in the first direction is greater than a divergence angle of the laser beam incident on the first collimating portion in the second direction. The first direction is parallel to a fast axis direction of the laser beam incident on the first collimating portion, and the second direction is parallel to a slow axis direction of the laser beam incident on the first collimating portion. The first direction is perpendicular to the second direction. The second collimating portion is a surface of the collimating lens away from the plurality of light-emitting chips, and the second collimating portion and the first collimating portion are arranged at an interval. The second collimating portion is configured to: collimate an incident laser beam in the second direction, such that a divergence angle of a laser beam exiting from the second collimating portion in the first direction remains unchanged, and a divergence angle of the laser beam exiting from the second collimating portion in the second direction is reduced to 0°. A change amount between a divergence angle of the laser beam incident on the second collimating portion in the second direction and the divergence angle of the laser beam exiting from the second collimating portion in the second direction is greater than a change amount between the divergence angle of the laser beam incident on the first collimating portion in the second direction and the divergence angle of the laser beam exiting from the first collimating portion in the second direction.

In another aspect, a projection apparatus is provided. The projection apparatus includes a laser source assembly, a light modulation assembly, and a projection lens. The laser source assembly is configured to emit illumination beams. The laser source assembly includes the light-emitting device described above. The light modulation assembly is configured to modulate the illumination beams emitted by the laser source assembly, so as to obtain projection beams. The projection lens is configured to project the projection beams into an image.

In yet another aspect, a light-emitting device is provided. The light-emitting device includes a plurality of light-emitting chips and a collimating lens. The plurality of light-emitting chips are arranged in an array along a first direction and a second direction and configured to emit laser beams in the first direction. The collimating lens is disposed on laser-exit sides of the plurality of light-emitting chips. The collimating lens is configured to collimate the incident laser beams. The collimating lens includes a first collimating portion and a second collimating portion. The first collimating portion is a surface of the collimating lens facing the plurality of light-emitting chips. The first collimating portion is configured to: collimate an incident laser beam in a third direction and reduce a divergence angle of the incident laser beam in the second direction, such that a divergence angle of a laser beam exiting from the first collimating portion in the third direction is reduced to 0°, a divergence angle of the laser beam exiting from the first collimating portion in the second direction is reduced, and the divergence angle of the laser beam exiting from the first collimating portion in the second direction is greater than 0°. A divergence angle of the laser beam incident on the first collimating portion in the third direction is greater than a divergence angle of the laser beam incident on the first collimating portion in the second direction. The second direction is parallel to a slow axis direction of the laser beam incident on the first collimating portion, and the third direction is parallel to a fast axis direction of the laser beam incident on the first collimating portion. The first direction, the second direction, and the third direction are perpendicular to each other. The second collimating portion is a surface of the collimating lens away from the plurality of light-emitting chips, and the second collimating portion and the first collimating portion are arranged at an interval. The second collimating portion is configured to: collimate an incident laser beam in the second direction, such that a divergence angle of a laser beam exiting from the second collimating portion in the third direction remains unchanged, and a divergence angle of the laser beam exiting from the second collimating portion in the second direction is reduced to 0°. A change amount between a divergence angle of the laser beam incident on the second collimating portion in the second direction and the divergence angle of the laser beam exiting from the second collimating portion in the second direction is greater than a change amount between the divergence angle of the laser beam incident on the first collimating portion in the second direction and the divergence angle of the laser beam exiting from the first collimating portion in the second direction. The first collimating portion includes a first collimating sub-portion, and the first collimating sub-portion extends along the second direction. The second collimating portion includes a plurality of second collimating sub-portions. The plurality of second collimating sub-portions are arranged along the second direction, and each of the plurality of second collimating sub-portions extends along the third direction.

In yet another aspect, a light-emitting device is provided. The light-emitting device includes a plurality of light-emitting chips and a collimating lens. The plurality of light-emitting chips are configured to emit laser beams. The collimating lens is located on laser-exit sides of the plurality of light-emitting chips and is configured to receive the laser beams from the plurality of light-emitting chips and collimate the incident laser beams. The collimating lens includes a first region, a second region, and a beam path adjusting component. The first region is configured to collimate a laser beam incident on the first region. The second region is located on at least one side of the first region in at least one of a first direction or a second direction. The first direction and the second direction each are perpendicular to a thickness direction of the collimating lens. The beam path adjusting component is located in the second region and configured to adjust a beam path of a laser beam incident on the second region, such that the adjusted laser beam is incident on the first region.

In some embodiments, the collimating lens further includes a groove. A side of the collimating lens facing the plurality of light-emitting chips is recessed in a direction away from the plurality of light-emitting chips, to form the groove. The groove includes a bottom surface and a side wall. The bottom surface is a laser-incident surface of the collimating lens and located in the first region. The side wall serves as a first adjusting sub-component. The first adjusting sub-component is located in the second region and is configured to: adjust the beam path of the laser beam incident on the second region, such that the laser beam incident on the second region is incident on the first region. The beam path adjusting component includes the first adjusting sub-component.

In some embodiments, the first adjusting sub-component satisfies at least one of the following: a first angle between the first adjusting sub-component and the laser-incident surface is greater than or equal to 110° and less than or equal to 140°; alternatively, in a thickness direction of the collimating lens, a depth of the groove is greater than or equal to 0.5 mm and less than or equal to 0.7 mm.

In some embodiments, the collimating lens further includes a target curved surface. The target curved surface is a surface of the collimating lens away from the laser-incident surface and located in the first region. The target curved surface protrudes in a direction away from the laser-incident surface. A thickness of the target curved surface is greater than or equal to 0.8 mm and less than or equal to 1.1 mm. A thickness of the collimating lens is greater than or equal to 1.5 mm and less than or equal to 2.5 mm.

In some embodiments, the beam path adjusting component includes a second adjusting sub-component. The second adjusting sub-component includes two side walls of the collimating lens in the first direction. The second adjusting sub-component is configured to: adjust the beam path of the laser beam incident on the second region, such that the laser beam incident on the second region is incident on the first region. The collimating lens further includes a laser-incident surface. The laser-incident surface is a surface of the collimating lens facing the plurality of light-emitting chips and located in the first region and the second region.

In some embodiments, a second angle between the second adjusting sub-component and the laser-incident surface is greater than or equal to 40° and less than or equal to 50°.

In some embodiments, the collimating lens further includes a target curved surface. The target curved surface is a surface of the collimating lens away from the laser-incident surface and located in the first region. The target curved surface protrudes in a direction away from the laser-incident surface. A thickness of the target curved surface is greater than or equal to 0.8 mm and less than or equal to 1.1 mm. In a thickness direction of the collimating lens, a minimum distance between the target curved surface and the laser-incident surface is greater than or equal to 0.7 mm and less than or equal to 0.9 mm.

In some embodiments, a thickness of the collimating lens is greater than or equal to 1.5 mm and less than or equal to 2.0 mm. An optical path between any one of the plurality of light-emitting chips and the laser-incident surface of the collimating lens is greater than or equal to 1.9 mm and less than or equal to 2.2 mm. A width of the first region in the first direction is greater than or equal to 3.0 mm and less than or equal to 3.4 mm.

In some embodiments, the collimating lens further includes a microstructure surface. The microstructure surface includes a portion of a surface of the collimating lens away from the plurality of light-emitting chips and is located in the second region. The microstructure surface is configured to collimate a laser beam incident on the microstructure surface. The microstructure surface includes at least one of a Fresnel structure surface or a diffractive optical element.

### BRIEF DESCRIPTION OF THE DRAWINGS

FIG. 1 is a diagram showing a structure of a light-emitting device in the related art;

FIG. 2 is a diagram showing another structure of a light-emitting device in the related art;

FIG. 3 is a schematic diagram of a beam spot of a light-emitting device in the related art;

FIG. 4A is a diagram showing a structure of a projection apparatus, in accordance with some embodiments;

FIG. 4B is a diagram showing another structure of a projection apparatus, in accordance with some embodiments;

FIG. 4C is a diagram showing yet another structure of a projection apparatus, in accordance with some embodiments;

FIG. 4D is a diagram showing a beam path of a laser source assembly, a light modulation assembly, and a projection lens in a projection apparatus, in accordance with some embodiments;

FIG. 4E is a diagram showing an arrangement of micromirrors in a digital micromirror device, in accordance with some embodiments;

FIG. 4F is a diagram showing a swing position of the micromirror in FIG. 4E;

FIG. 4G is a schematic diagram showing operation of micromirrors, in accordance with some embodiments;

FIG. 4H is a diagram showing yet another structure of a projection apparatus, in accordance with some embodiments;

FIG. 4I is a diagram showing yet another structure of a projection apparatus, in accordance with some embodiments;

FIG. 5A is a diagram showing a structure of a light-emitting device, in accordance with some embodiments;

FIG. 5B is an exploded view of a light-emitting device, in accordance with some embodiments;

FIG. 5C is a diagram showing another structure of a light-emitting device, in accordance with some embodiments;

FIG. 5D is a diagram showing yet another structure of a light-emitting device, in accordance with some embodiments;

FIG. 5E is a diagram showing yet another structure of a light-emitting device, in accordance with some embodiments;

FIG. 6 is a sectional view of the light-emitting device in FIG. 5E taken along the line AA′;

FIG. 7 is a diagram showing yet another structure of a light-emitting device, in accordance with some embodiments;

FIG. 8A is a top view of the light-emitting device in FIG. 7;

FIG. 8B is a diagram showing a structure of a light-emitting chip, in accordance with some embodiments;

FIG. 8C is a diagram showing a structure of a light-emitting assembly and a collimating lens, in accordance with some embodiments;

FIG. 9 is a perspective view of a collimating lens, in accordance with some embodiments;

FIG. 10 is another perspective view of a collimating lens, in accordance with some embodiments;

FIG. 11 is a diagram showing a structure of a collimating lens, in accordance with some embodiments;

FIG. 12 is a diagram showing another structure of a collimating lens, in accordance with some embodiments;

FIG. 13 is a diagram showing yet another structure of a light-emitting device, in accordance with some embodiments;

FIG. 14 is a schematic diagram of a laser beam passing through a collimating lens, in accordance with some embodiments;

FIG. 15 is another schematic diagram of a laser beam passing through a collimating lens, in accordance with some embodiments;

FIG. 16 is a schematic diagram of a beam spot of a light-emitting device, in accordance with some embodiments;

FIG. 17 is another schematic diagram of a beam spot of a light-emitting device, in accordance with some embodiments;

FIG. 18 is yet another schematic diagram of a beam spot of a light-emitting device, in accordance with some embodiments;

FIG. 19 is a diagram showing yet another structure of a light-emitting device, in accordance with some embodiments;

FIG. 20 is a schematic diagram of a beam spot divergence process of a light-emitting device, in accordance with some embodiments;

FIG. 21 is a diagram showing yet another structure of a collimating lens, in accordance with some embodiments;

FIG. 22 is a sectional view of a collimating lens, in accordance with some embodiments;

FIG. 23 is a diagram showing yet another structure of a light-emitting device, in accordance with some embodiments;

FIG. 24 is another sectional view of a collimating lens, in accordance with some embodiments;

FIG. 25 is yet another sectional view of a collimating lens, in accordance with some embodiments;

FIG. 26 is a diagram showing yet another structure of a light-emitting device, in accordance with some embodiments;

FIG. 27 is yet another sectional view of a collimating lens, in accordance with some embodiments;

FIG. 28 is yet another sectional view of a collimating lens, in accordance with some embodiments;

FIG. 29 is yet another sectional view of a collimating lens, in accordance with some embodiments;

FIG. 30 is a diagram showing a structure of a diffractive optical element, in accordance with some embodiments;

FIG. 31 is a diagram showing another structure of a diffractive optical element, in accordance with some embodiments;

FIG. 32 is a diagram showing yet another structure of a diffractive optical element, in accordance with some embodiments;

FIG. 33 is a diagram showing a structure of a Fresnel structural surface, in accordance with some embodiments;

FIG. 34 is a diagram showing yet another structure of a collimating lens, in accordance with some embodiments;

FIG. 35 is yet another sectional view of a collimating lens, in accordance with some embodiments;

FIG. 36 is a diagram showing yet another structure of a light-emitting device, in accordance with some embodiments;

FIG. 37 is a diagram showing yet another structure of a collimating lens, in accordance with some embodiments; and

FIG. 38 is a diagram showing yet another structure of a light-emitting device, in accordance with some embodiments.

### DETAILED DESCRIPTION

Some embodiments of the present disclosure will be clearly and completely described below with reference to the accompanying drawings. However, the described embodiments are merely some but not all embodiments of the present disclosure. All other embodiments obtained by a person of ordinary skill in the art based on embodiments provided in the present disclosure will be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the terms described above do not necessarily refer to the same embodiment(s) or example(s). In addition, the specific features, structures, materials, or characteristics may be included in any one or more embodiments or examples in any suitable manner.

Hereinafter, the terms such as “first” and “second” are used for descriptive purposes only and are not to be construed as indicating or implying the relative importance or implicitly indicating the number of indicated technical features. Thus, features defined by “first” or “second” may explicitly or implicitly include one or more of the features. In the description of some embodiments of the present disclosure, the term “a plurality of” or “the plurality of” means two or more unless otherwise specified.

In the description of some embodiments, the terms “coupled,” “connected,” and derivatives thereof may be used. The term “connected” will be understood in a broad sense. For example, the term “connected” may represent a fixed connection, a detachable connection, or a one-piece connection, or may represent a direct connection, or may represent an indirect connection through an intermediate medium. The term “coupled” means that two or more components are in direct physical or electrical contact with each other. The term “coupled” or “communicatively coupled” may also indicate that two or more components are not in direct contact with each other but still cooperate or interact with each other. The embodiments disclosed herein are not necessarily limited to the content herein.

The phrase “at least one of A, B, and C” has the same meaning as the phrase “at least one of A, B, or C,” both including the following combinations of A, B, and C: only A, only B, only C, a combination of A and B, a combination of A and C, a combination of B and C, and a combination of A, B, and C.

The phrase “applicable to” or “configured to” used herein means an open and inclusive expression, which does not exclude devices that are applicable to or configured to perform additional tasks or steps.

The terms such as “about,” “substantially,” and “approximately” as used herein include a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

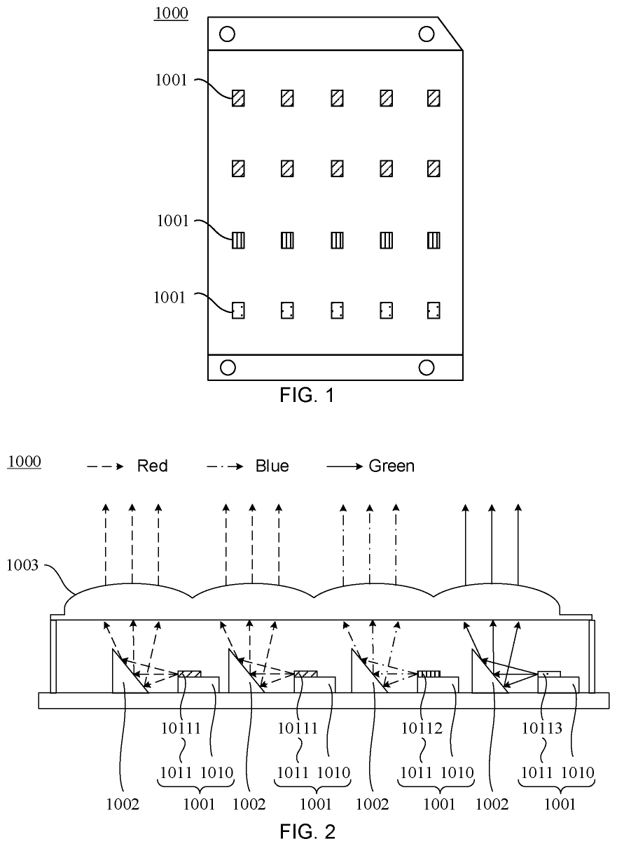

In general, as shown in FIGS. 1 and 2, a light-emitting device 1000 includes a plurality of light-emitting assemblies 1001. The plurality of light-emitting assemblies 1001 are arranged in an array and may be packaged on a substrate. The number of light-emitting assemblies 1001 is positively correlated with the luminous flux finally output by the light-emitting device 1000.

As shown in FIG. 2, the light-emitting assembly 1001 includes a light-emitting chip 1011. The light-emitting chip 1011 is configured to emit a laser beam. The plurality of light-emitting assemblies 1001 include a plurality of light-emitting chips 1011, and the plurality of light-emitting chips 1011 include a red light-emitting chip 10111, a blue light-emitting chip 10112 and a green light-emitting chip 10113.

It will be noted that the red light-emitting chip 10111 may refer to a light-emitting chip 1011 that emits a red laser beam; the blue light-emitting chip 10112 may refer to a light-emitting chip 1011 that emits a blue laser beam; and the green light-emitting chip 10113 may refer to a light-emitting chip 1011 that emits a green laser beam.

As shown in FIG. 2, the light-emitting assembly 1001 further includes a plurality of heat sinks 1010 (heat sink substrates). The light-emitting chip 1011 is disposed on the heat sink 1010. The heat sink 1010 is configured to dissipate heat from the light-emitting chip 1011.

As shown in FIG. 2, the light-emitting device 1000 further includes a plurality of reflecting lenses 1002. The reflecting lens 1002 is configured to reflect the laser beam emitted by the light-emitting chip 1011. For example, the laser beam emitted by the light-emitting chip 1011 is deflected by 90° after passing through the reflecting lens 1002.

As shown in FIG. 2, the light-emitting device 1000 further includes a collimating lens 1003. The collimating lens 1003 is configured to collimate the laser beam reflected by the reflecting lens 1002.

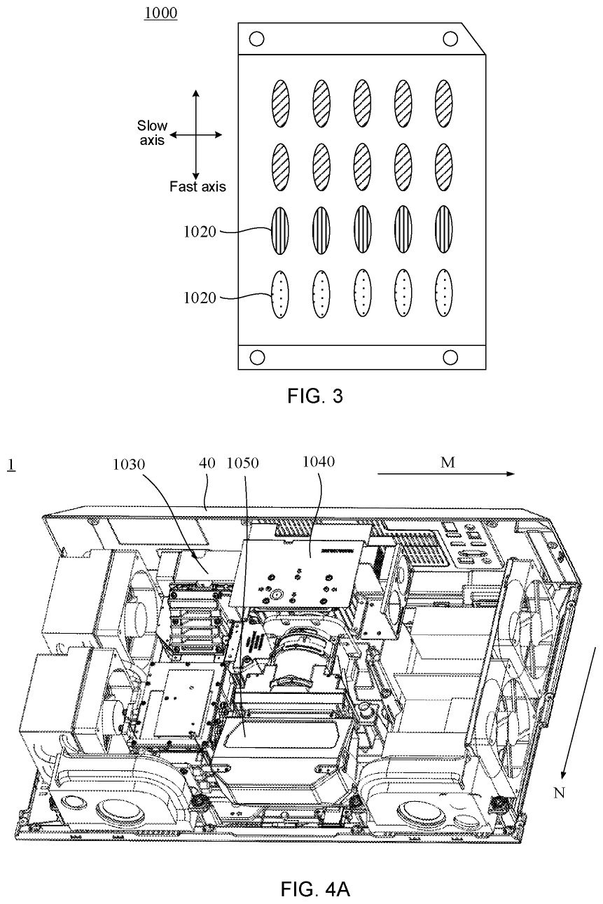

Since a divergence angle of the laser beam in a fast axis direction is greater than a divergence angle of the laser beam in a slow axis direction, as shown in FIG. 3, a beam spot 1020 formed by the laser beam at the collimating lens 1003 has an elliptical shape after the laser beam is collimated by the collimating lens 1003. A major axis direction (also being referred to as a long axis direction) of the beam spot 1020 is parallel to the fast axis direction, and a minor axis direction (also being referred to as a short axis direction) of the beam spot 1020 is parallel to the slow axis direction. Since a dimension of the beam spot 1020 in the fast axis direction is significantly greater than a dimension of the beam spot 1020 in the slow axis direction, a homogenization effect for the beam spot 1020 differs between the fast and slow axis directions, affecting the homogenization effect and speckle reduction effect for the beam spot 1020.

To this end, a projection apparatus 1 is provided in some embodiments of the present disclosure. The projection apparatus 1 includes a light-emitting device 100. The light-emitting device 100 includes a first collimating portion 31 and a second collimating portion 32. The first collimating portion 31 collimates an incident laser beam in the fast axis direction and reduces a divergence angle of the incident laser beam in the slow axis direction, where the reduced divergence angle is greater than 0°. The second collimating portion 32 collimates an incident laser beam in the slow axis direction. In this way, a minor axis dimension (i.e., a dimension of a beam spot in the minor axis direction) of a beam spot formed by the laser beam at the second collimating portion 32 is greater than a minor axis dimension of a beam spot formed by the laser beam at the first collimating portion 31. As a result, it is possible to reduce a difference between a major axis dimension (i.e., a dimension of a beam spot in the major axis direction) and a minor axis dimension of the beam spot, which is conducive to improving the homogenization effect and speckle reduction effect for the beam spot.

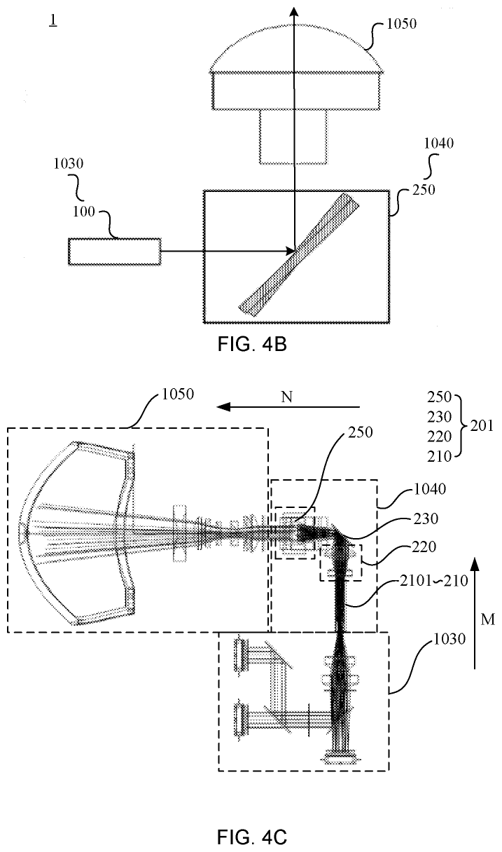

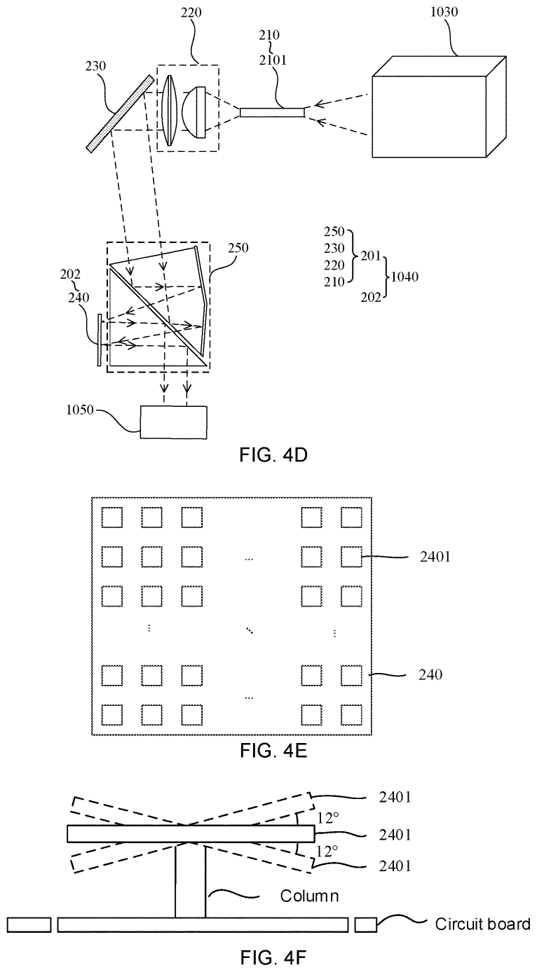

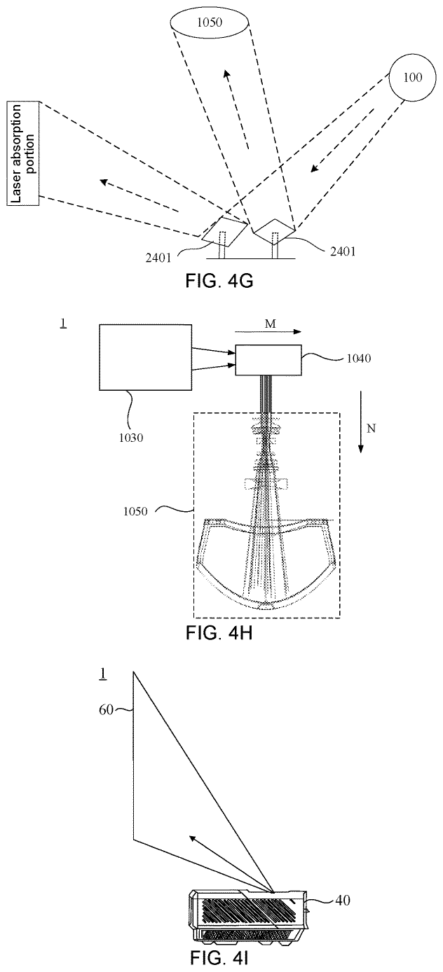

As shown in FIG. 4A, the projection apparatus 1 includes a laser source assembly 1030. The laser source assembly 1030 is configured to provide illumination beams (i.e., laser beams). The projection apparatus 1 further includes a light modulation assembly 1040. The light modulation assembly 1040 is configured to modulate the illumination beams provided by the laser source assembly 1030 with image signals, so as to obtain projection beams. The projection apparatus 1 further includes a projection lens 1050. The projection lens 1050 is configured to project the projection beams into an image on a screen or a wall. The projection apparatus 1 further includes an apparatus housing 40 (only a portion of the apparatus housing 40 being shown in FIG. 4A), and the laser source assembly 1030, the light modulation assembly 1040, and the projection lens 1050 are assembled in the apparatus housing 40.

The laser source assembly 1030, the light modulation assembly 1040, and the projection lens 1050 are sequentially connected in a propagation direction of the beams and are each wrapped by a corresponding housing. The housings of the laser source assembly 1030, the light modulation assembly 1040, and the projection lens 1050 each support their corresponding optical components, and make the optical components satisfy preset sealing or airtight requirements.

A first end of the light modulation assembly 1040 is connected to the laser source assembly 1030, and the laser source assembly 1030 and the light modulation assembly 1040 are arranged along an exit direction (referring to the direction M shown in FIG. 4A) of the illumination beams of the projection apparatus 1. A second end of the light modulation assembly 1040 is connected to the projection lens 1050, and the light modulation assembly 1040 and the projection lens 1050 are arranged along an exit direction (referring to the direction N shown in FIG. 4A) of the projection beams of the projection apparatus 1. The exit direction M of the illumination beams is substantially perpendicular to the exit direction N of the projection beams. In one aspect, such connection structure may adapt to characteristics of a beam path of a reflective light valve in the light modulation assembly 1040, and in another aspect, it is also conducive to shortening a length of a beam path in a one-dimensional direction, which is helpful for structural arrangement of the apparatus. For example, in a case where the laser source assembly 1030, the light modulation assembly 1040, and the projection lens 1050 are disposed in a one-dimensional direction (e.g., the direction M), the length of the beam path in the one-dimensional direction is long, which is not conducive to the structural arrangement of the apparatus. The reflective light valve will be described below.

In some embodiments, the laser source assembly 1030 may sequentially provide beams of three primary colors (beams of other colors may also be added on a basis of the beams of the three primary colors). Due to a phenomenon of visual perception of human eyes, what the human eyes see is white beams formed by mixing the beams of three primary colors. Alternatively, the laser source assembly 1030 may also simultaneously output the beams of three primary colors, so as to continuously emit the white beams. As shown in FIG. 4B, the laser source assembly 1030 includes a light-emitting device 100 that may emit a laser beam of at least one color, such as a red laser beam, a blue laser beam or a green laser beam.

The illumination beams emitted by the laser source assembly 1030 enter the light modulation assembly 1040. As shown in FIGS. 4C and 4D, the light modulation assembly 1040 includes an illumination lens group 201 and a light modulation device (or the light valve) 202. The illumination lens group 201 is configured to receive the illumination beams provided by the laser source assembly 1030 and transmit the illumination beams to the light modulation device 202 at a set angle and direction. The light modulation device 202 is configured to modulate the illumination beams to obtain the projection beams and reflect the projection beams into the projection lens 1050.

In some embodiments, as shown in FIGS. 4C and 4D, the illumination lens group 201 includes a light-homogenizing component 210, a lens group 220, and a prism group 250. The light-homogenizing component 210 is configured to receive the illumination beams provided by the laser source assembly 1030 and homogenize the illumination beams. The lens group 220 is configured to converge the illumination beams exiting from the light-homogenizing component 210 to the prism group 250. The prism group 250 is configured to reflect the illumination beams to the light modulation device 202.

In some embodiments, as shown in FIGS. 4C and 4D, the light-homogenizing component 210 includes a light pipe 2101. A light outlet of the light pipe 2101 may be in a shape of a rectangle, so as to have a shaping effect on a beam spot. In this way, the shape of the beam spot of the illumination beams exiting from the light pipe 2101 may match a rectangular laser-receiving surface of the light modulation device 202. Alternatively, the light-homogenizing component 210 may include a fly-eye lens. The fly-eye lens may homogenize the incident illumination beams and shape the illumination beams, so as to output a rectangular beam spot.

In some embodiments, as shown in FIGS. 4C and 4D, the illumination lens group 201 further includes a reflector 230. The reflector 230 is located on a laser-exit side of the lens group 220 and configured to reflect the illumination beams exiting from the lens group 220 to the prism group 250.

In some embodiments, as shown in FIG. 4D, the light modulation device 202 includes a digital micromirror device (DMD) 240.

The DMD 240 is a core component in the light modulation assembly 1040 and configured to modulate the illumination beams provided by the laser source assembly 1030 with image signals. That is to say, the DMD 240 controls the illumination beams to display different luminance and gray scales according to different pixels in an image to be projected, so as to finally produce an optical image.

The DMD 240 is applied in a Digital Light Processing (DLP) projection architecture. As shown in FIGS. 2 and 4D, the light modulation assembly 1040 uses the DLP projection architecture. As shown in FIG. 4E, the DMD 240 includes thousands of micromirrors 2401 that may be individually driven to rotate. These micromirrors 2401 are arranged in an array. One micromirror 2401 (e.g., each micromirror 2401) corresponds to one pixel in the image to be projected. In the DLP projection architecture, each micromirror 2401 is equivalent to a digital switch. The micromirror 2401 may swing within a range of plus or minus 12° (i.e., ±12°) or a range of plus or minus 17° (i.e., ±17°) due to the action of an external electric field, so that the reflected beam may be imaged on the screen along an optical axis direction by the projection lens 1050, forming a bright pixel.

For example, as shown in FIG. 4F, for the micromirrors 2401 with the deflection angles of ±12°, a state at +12° is an ON state, and a state at −12° is an OFF state. For a deflection angle between −12° and +12°, actual operating states of the micromirror 2401 are only the ON state and the OFF state. As shown in FIG. 4G, a laser beam reflected by the micromirror 2401 at a negative deflection angle is referred to as an OFF laser beam, and the OFF laser beam is an ineffective laser beam, which is usually incident on the housing of the light modulation assembly 1040, or is absorbed by a laser absorption portion. A laser beam reflected by the micromirror 2401 at a positive deflection angle is referred to as an ON laser beam. The ON laser beam is an effective beam reflected by the micromirror 2401 on a surface of the DMD 240 when the micromirror 2401 receives irradiation of the illumination beams, and the ON laser beam enters the projection lens 1050 at a positive deflection angle for projection imaging. In a display cycle of a frame of an image, some or all of the micromirrors 2401 are switched once between the ON state and the OFF state, so that gray scales of pixels in the frame of the image are achieved according to durations of the micromirrors 2401 in the ON state and the OFF state.

The light-homogenizing component 210, the lens group 220, and the reflector 230 at a front end of the DMD 240 form an illumination path, and the illumination beams emitted by the laser source assembly 1030 have a size and an incident angle which satisfy the requirements of the DMD 240 after passing through the illumination path.

In some embodiments, as shown in FIG. 4H, the projection lens 1050 includes a combination of a plurality of lenses, which are usually divided by groups, and are divided into a three-segment combination including a front group, a middle group, and a rear group, or a two-segment combination including a front group and a rear group. The front group is a lens group proximate to a laser-exit side (i.e., a side of the projection lens 1050 away from the light modulation assembly 1040 in the direction N in FIG. 4H) of the projection apparatus 1, and the rear group is a lens group proximate to a laser-exit side (i.e., a side of the projection lens 1050 proximate to the light modulation assembly 1040 in the opposite direction of the direction N in FIG. 4H) of the light modulation assembly 1040. The projection lens 1050 may include a zoom projection lens, or a prime focus-adjustable projection lens, or a prime projection lens.

In some embodiments, the projection apparatus 1 is an ultra-short-focus projection apparatus, and the projection lens 1050 is an ultra-short-focus projection lens. A projection ratio of the projection lens 1050 is usually less than 0.3, such as 0.24. In a case of a same projection distance, the smaller the projection ratio, the larger the projection image of the projection apparatus 1. The ultra-short-focus projection lens with a lesser projection ratio may adapt to a narrow space while ensuring the projection effect. In this way, the laser projection apparatus 1 may perform a large-sized projection display with a small projection ratio.

In some embodiments, as shown in FIG. 4I, the projection apparatus 1 further includes a projection screen 60. The projection screen 60 is located on a laser-exit path of the projection lens 1050 and may reflect the projection beam exiting from the projection lens 1050 to display the projection image.

The light-emitting device 100 of the laser source assembly 1030 in the present disclosure will be introduced in detail below.

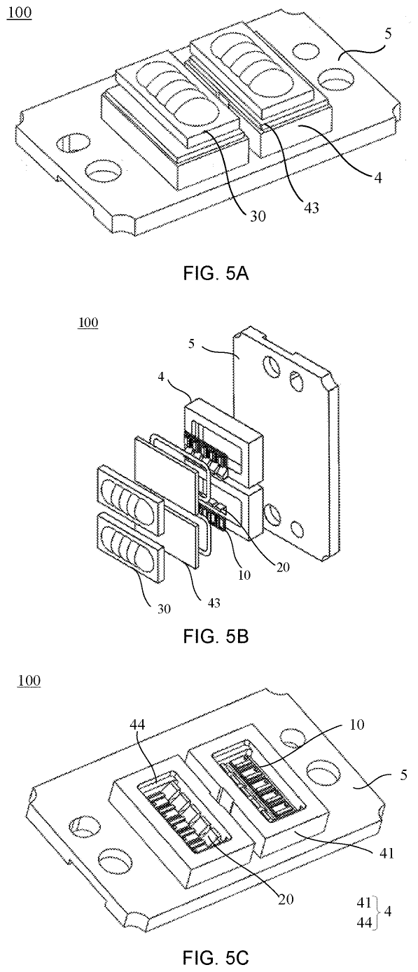

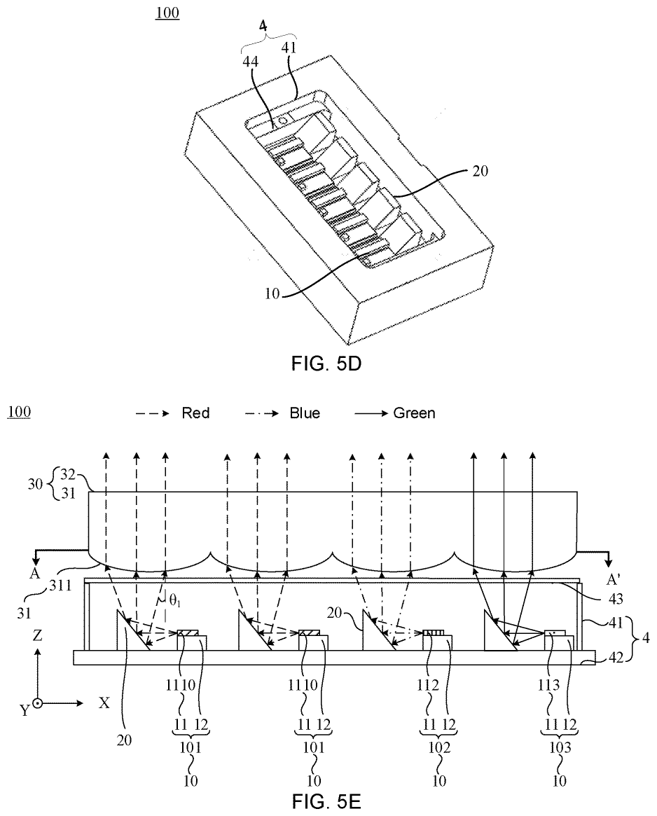

In some embodiments, as shown in FIGS. 5A to 5C, the light-emitting device 100 includes a base plate 5 and at least one package 4. The package 4 is disposed on the base plate 5. For example, the package 4 and the base plate 5 are fixed together by means of reflow soldering using a tin-silver-copper alloy. For example, the package 4 and the base plate 5 are fixed together by means of high-temperature and pressure sintering of silver paste (or copper paste).

In some embodiments, the base plate 5 includes a printed circuit board, so as to achieve electrical interconnection between the base plate 5 and the package 4. The base plate 5 may be made of metal materials such as oxygen-free copper and red copper.

In some embodiments, as shown in FIGS. 5A to 5C, at least one package 4 includes a plurality of packages 4. The plurality of packages 4 each are disposed on the base plate 5.

In some embodiments, as shown in FIGS. 5C to 5E, the package 4 includes a sidewall (i.e., package side walls) 41. The sidewall 41 may be made of a ceramic material or a metal alloy material.

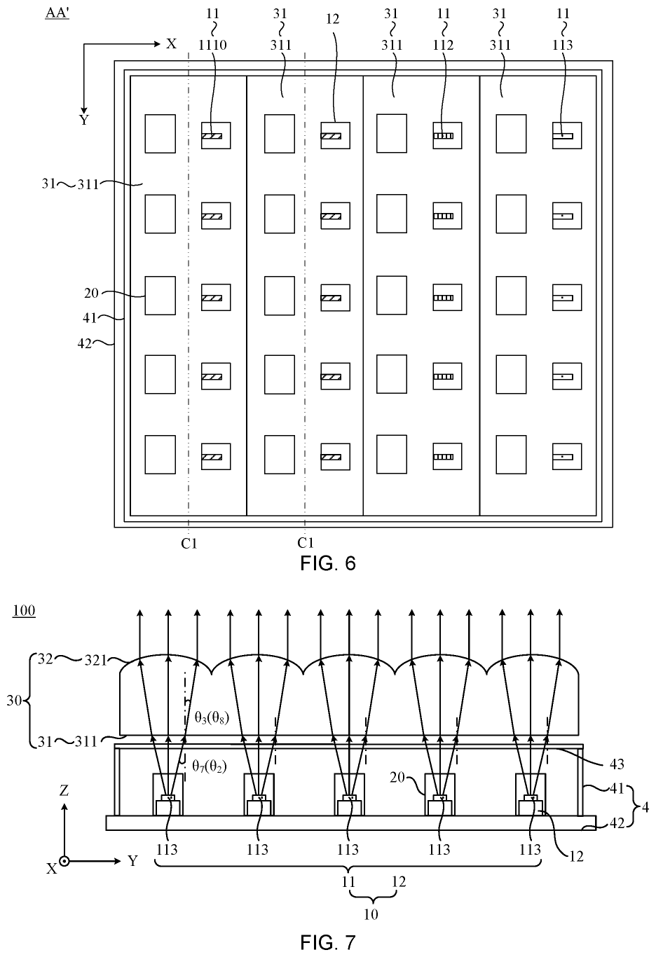

In some embodiments, as shown in FIGS. 5E and 6, the package 4 further includes a substrate 42. The substrate 42 has high flatness, so as to increase the mounting accuracy of the components on the substrate 42. The substrate 42 may be made of materials with good heat dissipation, such as oxygen-free copper and diamond. A rectangular portion in the middle of the substrate 42 serves as a circuit isolation region. The substrate 42 and the sidewall 41 may be formed into a single piece by a sintering process.

It will be noted that an identification region may be disposed on a side of the sidewall 41, so as to identify, in a case where the substrate 42 serves as a part of the base plate 5, the orientation or direction of the sidewall 41.

In some embodiments, as shown in FIGS. 5C and 5D, the package 4 further includes steps 44. In a length direction of the package 4, the steps 44 are located on two sides inside the sidewall 41. The step 44 is coated with a metal film, and the steps 44 are connected to the substrate 42, so as to be connected to the base plate 5. A circular hole in a middle portion of step 44 may serve as an identification region to mark or identify a position or other information of the package 4.

In some embodiments, as shown in FIGS. 5E and 7, the light-emitting device 100 further includes a cover plate 43. The cover plate 43 is located on a side of the sidewall 41 away from the substrate 42 and is configured to increase airtightness of the package 4. The cover plate 43 may be made of high-strength sapphire or glass. The cover plate 43 includes a first region and a second region. The second region is a laser-transmissive region. The first region is located around the second region, and the first region is provided with a metal layer and an alloy solder, to facilitate welding of the cover plate 43 to the sidewall 41, thereby achieving airtightness of the package 4.

It will be noted that the higher the machining flatness of the first region, the thinner the solder layer. The first region includes a welding region. After the alloy solder melts at a temperature higher than the melting point, the solder may fill the welding region. If a thickness of the alloy solder is less than a thickness of the welding region of the package 4, the solder cannot completely fill the welding region, resulting in poor airtightness.

In some embodiments, as shown in FIGS. 5A and 5B, the base plate 5, the package 4 and the cover plate 43 form an accommodating cavity.

In some embodiments, as shown in FIGS. 5E and 7, the light-emitting device 100 further includes one or more light-emitting assemblies 10. The light-emitting assemblies 10 are arranged in a line in the accommodating cavity. The light-emitting assembly 10 is configured to emit the laser beam. The light-emitting assembly 10 is fixed on the substrate 42. For example, the light-emitting assembly 10 is fixed to the substrate 42 by a low-temperature sintering process using the nano-metal paste, so that the heat conduction performance and the high temperature mechanical reliability of the light-emitting assembly 10 after sintering are improved.

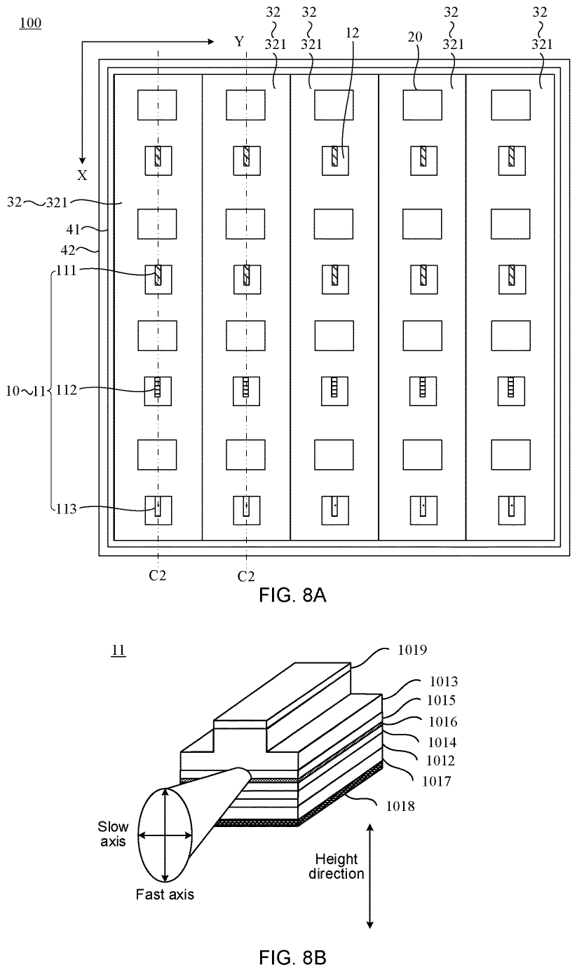

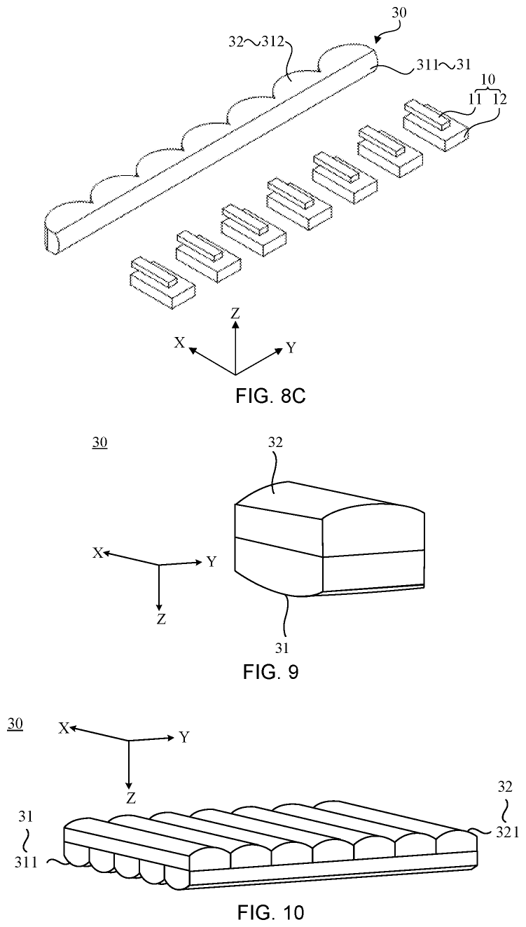

In some embodiments, as shown in FIGS. 7 and 8A, the light-emitting assembly 10 includes a light-emitting chip 11. The light-emitting assembly 10 further includes a heat sink 12. The light-emitting chip 11 is disposed on the heat sink 12. For example, the light-emitting chip 11 is soldered to the heat sink 12 via a eutectic process. The heat sink 12 may be made of materials with high thermal conductivity, for example, aluminum nitride (ALN) and silicon carbide (SIC).

In some embodiments, as shown in FIG. 8B, the light-emitting chip 11 includes an active layer 1016. The active layer 1016 is a core component of the light-emitting chip 11, and the active layer 1016 is configured to convert electrical energy into light energy and generate a laser beam. A width of the active layer 1016 is typically within a range of 100 μm to 500 μm, inclusive.

As shown in FIG. 8B, the light-emitting chip 11 further includes a first confinement layer 1015 and a second confinement layer 1014. The first confinement layer 1015 is disposed on a side of the active layer 1016, and the second confinement layer 1014 is disposed on another side of the active layer 1016 and is disposed opposite to the first confinement layer 1015. The first confinement layer 1015 and the second confinement layer 1014 may confine the propagation of laser beam in the active layer 1016. In this way, it is conducive to improving beam quality and reducing light leakage. The first confinement layer 1015 and the second confinement layer 1014 may also protect the active layer 1016 and prevent the active layer 1016 from being affected by the external environment.

As shown in FIG. 8B, the light-emitting chip 11 further includes a first waveguide layer 1013 and a second waveguide layer 1012. The first waveguide layer 1013 is located on a side of the first confinement layer 1015 away from the active layer 1016. The second waveguide layer 1012 is located on a side of the second confinement layer 1014 away from the active layer 1016. The first waveguide layer 1013 and the second waveguide layer 1012 each are made of materials with a high refractive index, such as, indium phosphide (InP) or gallium arsenide phosphide (GaAsP). By providing the first waveguide layer 1013 and the second waveguide layer 1012, light waves may be guided to propagate inside the chip, so that the laser beam is concentrated inside the active layer 1016.

As shown in FIG. 8B, the light-emitting chip 11 further includes a first electrode 1019 and a second electrode 1018. By providing the first electrode 1019 and the second electrode 1018, an electric field may be formed to supply current to the active layer, to excite laser emission.

As shown in FIG. 8B, the light-emitting chip 11 further includes a base 1017. The base 1017 is made of silicon or other semiconductor materials and serves as a substrate of the light-emitting chip 11.

It will be noted that dimensions of the first waveguide layer 1013 and the second waveguide layer 1012 in a height direction of the light-emitting chip 11 are small. Therefore, in the height direction of the light-emitting chip 11, the beam quality of the laser beam emitted from the light-emitting chip 11 is close to the diffraction limit, and the laser beam has a relatively large divergence angle.

In some embodiments, at least one light-emitting assembly 10 includes a plurality of light-emitting assemblies 10. The plurality of light-emitting assemblies 10 are arranged in an array. For example, the plurality of light-emitting assemblies 10 are arranged in rows and columns along a first direction X and a second direction Y.

In some embodiments, as shown in FIG. 5E, the plurality of light-emitting assemblies 10 include a first light-emitting assembly 101, a second light-emitting assembly 102 and a third light-emitting assembly 103. The number of first light-emitting assemblies 101 is greater than the number of second light-emitting assemblies 102 and the number of third light-emitting assemblies 103.

As shown in FIG. 5E, the first light-emitting assembly 101 includes a red light-emitting chip 1110 and a heat sink 12, the second light-emitting assembly 102 includes a green light-emitting chip 112 and a heat sink 12, and the third light-emitting assembly 103 includes a blue light-emitting chip 113 and a heat sink 12.

In some embodiments, as shown in FIGS. 5E and 6, the light-emitting device 100 further includes a reflecting lens 20. The reflecting lens 20 is disposed inside the accommodating cavity and on a laser-exit side of the light-emitting assembly 10. The reflecting lens 20 is configured to reflect a laser beam emitted by the light-emitting chip 11. For example, the reflecting lens 20 reflects the laser beam exiting from the light-emitting assembly 10 to the cover plate 43. The reflecting lens 20 may be made of materials such as borosilicate glass, quartz, and silicon. A reflecting surface of the reflecting lens 20 is coated with a reflective film to improve reflectivity. The reflecting lens 20 is fixed to the substrate 42. For example, the reflecting lens 20 is fixed to the substrate 42 by a low-temperature sintering process using nano-metal paste.

In some embodiments, as shown in FIGS. 5E and 6, the light-emitting device 100 further includes a collimating lens 30. The collimating lens 30 is located on the laser-exit side of the light-emitting assembly 10. The collimating lens 30 is configured to collimate the laser beam exiting from the laser-exit side and then output the laser beam. For example, the laser beam passes through the cover plate 43 and is incident on the collimating lens 30, and then exits from the collimating lens 30 after being collimated by the collimating lens 30. It may be understood that the collimating lens 30 being located on the laser-exit side of the light-emitting assembly 10 may mean that the collimating lens 30 is located on a laser-exit path of the light-emitting assembly 10.

In some embodiments, as shown in FIGS. 5A and 5B, the collimating lens 30 is directly disposed on the cover plate 43. For example, the collimating lens 30 may be fixed by applying adhesive to four corners of the collimating lens 30, and the positions to which the adhesive is applied are required to avoid the laser-transmissive region.

It will be noted that, as shown in FIGS. 5E and 6, the laser beam may exit from a top surface of the light-emitting device 100. Alternatively, the laser beam may also exit from a side of the light-emitting device 100. In a case where the laser beam exits from the side of the light-emitting device 100, the reflecting lens 20 may be omitted. The top surface may refer to a plane on which the cover plate 43 is located. The side may refer to a plane on which at least one wall surface of the sidewall 41 is located.

It will be noted that a divergence angle of a laser beam emitted by the light-emitting assembly 10 in the fast axis direction of the laser beam is greater than a divergence angle of the laser beam in the slow axis direction of the laser beam. For example, a divergence angle of a laser beam emitted by the light-emitting assembly 10 in the fast axis direction of the laser beam is any value within a range of 40° to 60°, inclusive, and a divergence angle of the laser beam emitted by the light-emitting assembly 10 in the slow axis direction of the laser beam is any value within a range of 6° to 15°, inclusive.

In a case where the laser beam exits from the top surface of the light-emitting device 100, as shown in FIGS. 5E and 7, the light-emitting assembly 10 emits a laser beam along the first direction X (or an opposite direction of the first direction X), the laser beam has a fourth divergence angle in the third direction Z, and a fifth divergence angle in the second direction Y, where the fourth divergence angle is greater than the fifth divergence angle. In this case, the fast axis direction of the laser beam is parallel to the third direction Z, and the slow axis direction of the laser beam is parallel to the second direction Y. Afterwards, the laser beam is deflected by 90° by the reflecting lens 20 and then incident on the collimating lens 30. As the propagation direction of the laser beam changes, the major axis direction of the beam spot formed at the collimating lens 30 is parallel to the first direction X, and the minor axis direction of the beam spot is parallel to the second direction Y. The first direction X, the second direction Y, and the third direction Z are perpendicular to each other.

In a case where the laser beam exits from the side of the light-emitting device 100, the light-emitting assembly 10 emits a laser beam along the first direction X (or the opposite direction of the first direction X), the fast axis direction of the laser beam is parallel to the third direction Z, and the slow axis direction of the laser beam is parallel to the second direction Y. The collimating lens 30 is located on the laser-exit side of the light-emitting assembly 10. The laser beam exiting from the light-emitting assembly 10 may be directly incident on the collimating lens 30. The major axis direction of the beam spot formed at the collimating lens 30 is parallel to the fast axis direction of the laser beam, and the minor axis direction of the beam spot is parallel to the slow axis direction of the laser beam.

The following description is given by considering an example in which the laser beam exits from the top surface of the light-emitting device 100.

In some embodiments, as shown in FIGS. 5E and 7, the collimating lens 30 includes a first collimating portion 31. The first collimating portion 31 is a side of the collimating lens 30 facing (or proximate to) the laser-exit side of the light-emitting assembly 10. The first collimating portion 31 is configured to collimate the laser beam in the first direction X.

The collimating lens 30 further includes a second collimating portion 32. The second collimating portion 32 is disposed opposite to the first collimating portion 31, and the second collimating portion 32 is a side of the collimating lens 30 away from the laser-exit side of the light-emitting assembly 10. The second collimating portion 32 is configured to collimate the laser beam in the second direction Y.

It will be noted that collimating the laser beam in a certain direction may be understood as the divergence angle of the laser beam in that direction being 0°. For example, collimating the laser beam in the first direction X may be understood as adjusting the divergence angle of the laser beam in the first direction X to 0°; collimating the laser beam in the second direction Y may be understood as adjusting the divergence angle of the laser beam in the second direction Y to 0°.

For example, as shown in FIGS. 9 and 10, the collimating lens 30 is a double-sided collimating lens. The first collimating portion 31 is a side of the double-sided collimating lens facing the laser-exit side of the light-emitting assembly 10. The second collimating portion 32 is a side of the double-sided collimating lens away from the laser-exit side of the light-emitting assembly 10. It will be noted that the double-sided collimating lens may focus an incident laser beam in a direction and diverge an incident laser beam in another direction. The double-sided collimating lens has two surfaces with different curvatures. For example, the first curved surface focuses the laser beams, while the second curved surface diverges the laser beams.

In the first direction X, the first collimating portion 31 is a curved surface and the second collimating portion 32 is a plane; in the second direction Y, the first collimating portion 31 is a plane and the second collimating portion 32 is a curved surface.

In some embodiments, the first collimating portion 31 and the second collimating portion 32 may be a one-piece member, so as to facilitate processing and manufacturing of the collimating lens 30. Alternatively, the first collimating portion 31 and the second collimating portion 32 may be separate pieces, so as to facilitate assembly and disassembly of the collimating lens 30.

The laser beam about to exit from the light-emitting device 100 passes sequentially through the first collimating portion 31 and the second collimating portion 32. As shown in FIG. 5E, when the laser beam is incident on the first collimating portion 31, the laser beam has a first divergence angle θ₁ in the first direction X. The first collimating portion 31 reduces the divergence angle of the laser beam in the first direction X to 0°, so that the laser beam is collimated in the first direction X. Since a curvature of the second collimating portion 32 in the first direction X is 0, the divergence angle of the laser beam in the first direction X remains unchanged after the laser beam passes through the second collimating portion 32. In this way, in the first direction X, a dimension (i.e., a major axis dimension of a beam spot) of the beam spot formed by the laser beam at the second collimating portion 32 is equal to a dimension of a beam spot formed by the laser beam at the first collimating portion 31.

As shown in FIG. 7, when the laser beam is incident on the first collimating portion 31, the laser beam has a second divergence angle θ₂ in the second direction Y. The second divergence angle θ₂ is less than the first divergence angle θ₁. An incident angle θ₇ of the laser beam at the first collimating portion 31 is equal to the second divergence angle θ₂ (i.e., θ₇=θ₂), and the laser beam is refracted after passing through the first collimating portion 31. A refraction angle θ₈ of the refracted laser beam is equal to a third divergence angle θ₃ of the laser beam in the second direction Y after passing through the first collimating portion 31 (i.e., θ₈=θ₃).

Since a refractive index n₁ of the collimating lens 30 is greater than a refractive index n₂ of air, according to the refraction equation n₂×sin θ₇=n₁×sin θ₈, it is possible to determine that the refraction angle θ₈ is less than the incident angle θ₇ (i.e., θ₈<θ₇). In this way, the divergence angle of the laser beam in the second direction Y after passing through the first collimating portion 31 is reduced, from the second divergence angle θ₂ to the third divergence angle θ₃, but the third divergence angle θ₃ is greater than 0°.

Thereafter, the refracted laser beam is incident on the second collimating portion 32 substantially along a thickness direction (e.g., the third direction Z) of the collimating lens 30. Since the refracted laser beam still has a certain divergence angle (i.e., the third divergence angle θ₃) in the second direction Y, as the optical path increases, in the second direction Y, a dimension (i.e., the minor axis dimension of the beam spot) of the beam spot formed by the laser beam at the second collimating portion 32 increases, and is greater than a dimension of the beam spot formed by the laser beam at the first collimating portion 31. In this way, the minor axis dimension of the beam spot increases, thereby reducing a difference between the major axis dimension and the minor axis dimension of the beam spot, improving the homogenization effect for the beam spot in the major axis direction and the minor axis direction, which is conducive to improving the homogenization and speckle reduction effect for the beam spot.

When the laser beam is incident on the second collimating portion 32, the second collimating portion 32 reduces the divergence angle of the laser beam in the second direction Y, so that the laser beam is collimated in the second direction Y.

In some embodiments, a change amount of the divergence angle of the laser beam in the second direction Y before and after exiting from the second collimating portion 32 is greater than a change amount of the divergence angle of the laser beam in the second direction Y before and after exiting from the first collimating portion 31. The change amount of the divergence angle of the laser beam in the second direction Y may be characterized by a difference between the divergence angles of the laser beam in the second direction Y before and after exiting from the second collimating portion 32. For example, a difference between the third divergence angle θ₃ and 0° is greater than a difference between the second divergence angle θ₂ and the third divergence angle θ₃.

For example, after the laser beam exiting from the light-emitting assembly 10 is reflected by the reflecting lens 20, a divergence angle of the reflected laser beam in the slow axis direction is 10° (i.e., the second divergence angle is) 10°. After being refracted by the first collimating portion 31, the divergence angle is reduced to 6° (i.e., the third divergence angle θ₃ is 6°). A change amount of the divergence angle of the laser beam in the second direction Y before and after exiting from the first collimating portion 31 is 4°. After the laser beam passes through the second collimating portion 32, the divergence angle is reduced to 0°, and a change amount of the divergence angle of the laser beam in the second direction Y before and after exiting from the second collimating portion 32 is 6°.

In a case where the light-emitting device 100 includes a plurality of light-emitting assemblies 10 arranged in an array, the first collimating portion 31 and the second collimating portion 32 are disposed corresponding to the plurality of light-emitting assemblies 10.

The following describes how the first collimating portion 31 and the second collimating portion 32 are disposed corresponding to the plurality of light-emitting assemblies 10.

In some embodiments, as shown in FIGS. 5E and 6, the first collimating portion 31 includes a plurality of first collimating sub-portions 311. The plurality of first collimating sub-portions 311 are arranged along the first direction X and each extends along the second direction Y. The first collimating sub-portion 311 corresponds to a row of light-emitting assemblies 10 arranged along the second direction Y. In this way, divergence angles of laser beams in the first direction X may be adjusted by the same first collimating sub-portion 311, where the laser beams are emitted by a row of light-emitting assemblies 10 arranged along the second direction Y. The first collimating sub-portion 311 may include a cylindrical lens.

In some embodiments, as shown in FIGS. 7 and 8A, the second collimating portion 32 includes a plurality of second collimating sub-portions 321. The plurality of second collimating sub-portions 321 are arranged along the second direction Y and each extends along the first direction X. The second collimating sub-portion 321 corresponds to a row of light-emitting assemblies 10 arranged along the first direction X. In this way, divergence angles of laser beams in the second direction Y may be adjusted by the same second collimating sub-portions 321, where the laser beams are emitted by a row of light-emitting assemblies 10 arranged along the first direction X. The second collimating sub-portion 321 may include a cylindrical lens. The direction in which the second collimating sub-portions 321 are arranged is perpendicular to the direction in which the first collimating sub-portions 311 are arranged.

It will be noted that the number of the first collimating sub-portions 311 and the second collimating sub-portions 321 is related to the arrangement and the number of the light-emitting assemblies 10. For example, as shown in FIGS. 6 and 8A, considering the first direction X as a column direction and the second direction Y as a row direction, in a case where the plurality of light-emitting assemblies 10 are arranged in an array of four rows and five columns, the collimating lens 30 includes four first collimating sub-portions 311 and five second collimating sub-portions 321. For another example, as shown in FIG. 13, the plurality of light-emitting assemblies 10 are arranged in an array of five rows and seven columns. In this case, as shown in FIGS. 10 to 12, the collimating lens 30 includes five first collimating sub-portions 311 and seven second collimating sub-portions 321. The present disclosure does not limit the number of the first collimating sub-portions 311 and the second collimating sub-portions 321, which may be configured according to requirements.

It may be understood that in a case where the laser beam exits from the side of the light-emitting device 100, the structure of the collimating lens 30 may be as shown in FIG. 8C, the collimating lens 30 is located on the laser-exit side of the light-emitting assembly 10. Two or more first collimating sub-portions 311 corresponding to a row of light-emitting assemblies 10 each extend along the second direction Y, and the two or more first collimating sub-portions 311 are arranged along the second direction Y. Moreover, the two or more first collimating sub-portions 311 may be a one-piece member. The second collimating sub-portions 321 corresponding to the row of light-emitting assemblies 10 each extends along the third direction Z, and the second collimating sub-portions 321 are arranged along the second direction Y. It will be noted that, in a case where the laser beam exiting from the side of the light-emitting device 100, since the fast axis direction of the laser beam incident on the collimating lens 30 is parallel to the third direction Z, the function of the first collimating portion 31 becomes collimating the incident laser beam in the third direction Z. The functions and effects of the collimating lens 30 in the scheme where the laser beam exits from the side of the light-emitting device 100 are similar to those of the collimating lens 30 in the scheme where the laser beam exits from the top surface of the light-emitting device 100, and details will not be repeated herein.

In this case, a plurality of rows of light-emitting assemblies 10 may emit laser beams in different directions (e.g., the first direction X, the opposite direction of the first direction X, the second direction Y, and the opposite direction of the second direction Y) perpendicular to the third direction Z. The light-emitting device 100 may include a plurality of collimating lenses 30, and the plurality of collimating lenses 30 may be located on laser-exit sides of the plurality of rows of light-emitting assemblies 10, respectively.

In some embodiments, in a case where the plurality of light-emitting assemblies 10 are arranged in a uniform array (i.e., in a case where row spacings between any two adjacent rows of the light-emitting assemblies 10 are equal to each other, and column spacings between any two adjacent columns of the light-emitting assemblies 10 are equal to each other), distances between center lines C1 (as shown in FIG. 6) of any two adjacent first collimating sub-portions 311 are equal to each other, and distances between center lines C2 (as shown in FIG. 8A) of any two adjacent second collimating sub-portions 321 are equal to each other.

In some embodiments, in a case where the plurality of light-emitting assemblies 10 are arranged in a non-uniform array (i.e., the row spacings between any two adjacent rows of the light-emitting assemblies 10 are different, or the column spacings between any two adjacent columns of the light-emitting assemblies 10 are different), the first collimating sub-portions 311 may be arranged according to rows of light-emitting assemblies 10, and the second collimating sub-portions 321 may be arranged according to columns of the light-emitting assemblies 10.

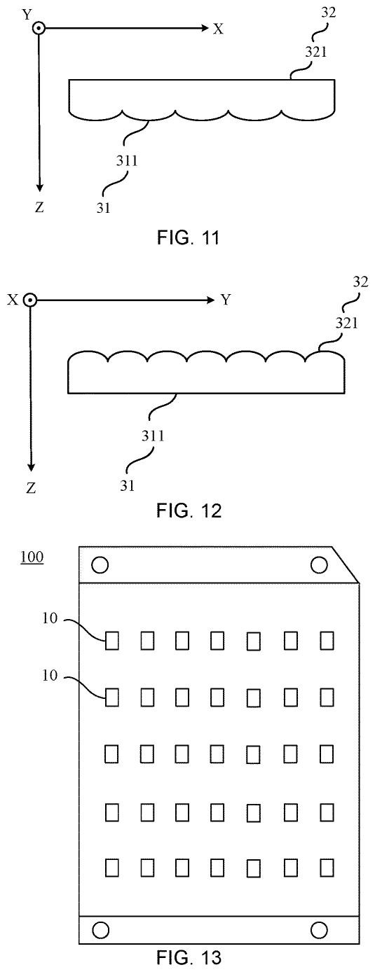

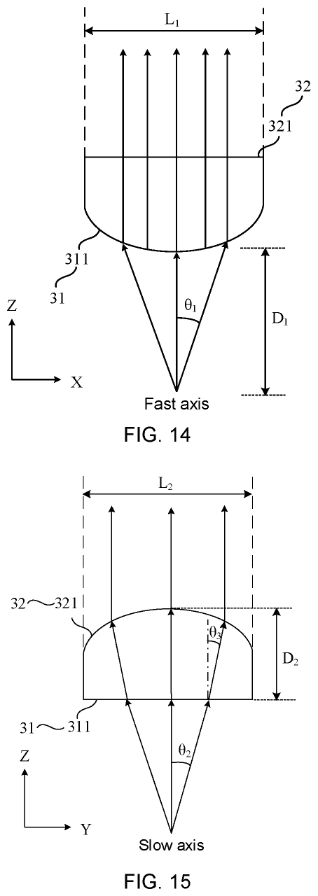

In some embodiments, as shown in FIGS. 11 and 14, the first collimating sub-portion 311 is a curved surface protruding toward the laser-exit side of the light-emitting assembly 10. A curvature of the curved surface in the first direction X is a variable value. The first collimating sub-portion 311 may adjust the divergence degree of the laser beam incident on the first collimating sub-portion 311 in the first direction X, and reduce the divergence angle of the laser beam in the first direction X, thereby achieving collimation of the laser beam in the first direction X. A curvature of the curved surface in the second direction Y is a constant value. For example, a point on the curved surface is selected, a line segment extends from this point along the second direction Y, and all points on the line segment have the same curvature. Since all points of the first collimating sub-portion 311 in the second direction Y have the same curvature, the first collimating sub-portion 311 cannot collimate the laser beam in the second direction Y. However, since the laser beam is refracted, the divergence angle of the laser beam in the second direction Y is reduced after the laser beam passes through the first collimating sub-portion 311.

In some embodiments, as shown in FIGS. 12 and 15, the second collimating sub-portion 321 is a curved surface protruding toward a direction away from the laser-exit side of the light-emitting assembly 10. A curvature of the curved surface in the second direction Y is a variable value. The second collimating sub-portion 321 may adjust the divergence degree of the laser beam incident on the second collimating sub-portion 321 in the second direction Y, and reduce the divergence angle of the laser beam in the second direction Y, thereby achieving collimation of the laser beam in the second direction Y. A curvature of the curved surface in the first direction X is a constant value. For example, a point on the curved surface is selected, a line segment extends from this point along the first direction X, and all points on the line segment have the same curvature. The second collimating sub-portion 321 cannot change the divergence angle of the laser beam in the first direction X.

In some embodiments, the curvature of the first collimating sub-portion 311 in the first direction X and the curvature of the second collimating sub-portion 321 in the second direction Y may also be constant values. In this case, the curved surfaces each may be in a shape of an arc. For example, an orthogonal projection of the first collimating sub-portion 311 on a plane formed by the first direction X and the third direction Z is a curve; an orthogonal projection of the first collimating sub-portion 311 on a plane formed by the second direction Y and the third direction Z is a straight line. An orthogonal projection of the second collimating sub-portion 321 on the plane formed by the first direction X and the third direction Z is a straight line; an orthogonal projection of the second collimating sub-portion 321 on the plane formed by the second direction Y and the third direction Z is a curve.

In some embodiments, as shown in FIGS. 14 and 15, the laser beam in the fast axis direction is collimated by the first collimating sub-portion 311, so that the divergence angle of the laser beam in the first direction X is adjusted from the first divergence angle θ₁ to 0°. The laser beam in the slow axis direction is refracted by the first collimating sub-portion 311. The divergence angle of the refracted laser beam in the second direction Y is adjusted from the second divergence angle θ₂ to the third divergence angle θ₃. The refracted laser beam is collimated by the second collimating sub-portion 321, and the divergence angle of the laser beam in the second direction Y is adjusted from the third divergence angle θ₃ to 0°.

In some embodiments, the third divergence angle θ₃ is greater than 0° and less than or equal to 10°. For example, the third divergence angle θ₃ is equal to 1°, 3°, 5°, 7°, or 10°. If the third divergence angle θ₃ is greater than 10°, the refracted laser beam may be incident on an edge of the collimating lens 30 and thus cannot be collimated by the second collimating sub-portion 321.

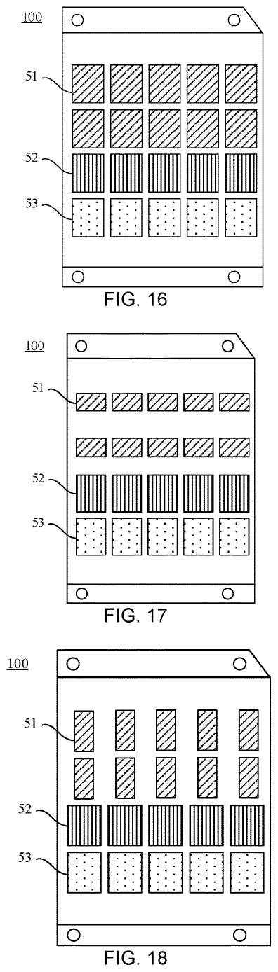

In some embodiments, as shown in FIG. 16, a beam spot formed by the laser beam after passing through the collimating lens 30 has a rectangular shape, and a ratio of a dimension of the beam spot in the fast axis direction to a dimension of the beam spot in the slow axis direction satisfies a preset condition, so as to improve the homogenization effect for the laser beam.

The preset condition is: D₁×tan θ₁=K₁×(D₁×tan θ₂+D₂×tan θ₃).

Herein, D₁ represents an optical path of the laser beam from the light-emitting assembly 10 to the first collimating sub-portion 311, and a thickness of the collimating lens 30 is defined as a second distance D₂. The second distance D₂ is a maximum distance between the first collimating sub-portion 311 and the second collimating sub-portion 321 in a direction from the first collimating sub-portion 311 to the second collimating sub-portion 321. For example, as shown in FIGS. 14 and 15, in the third direction Z, a distance between a lowest point of the first collimating sub-portion 311 and a highest point of the second collimating sub-portion 321 is the second distance D₂. The first divergence angle θ₁ is the divergence angle of the laser beam exiting from the light-emitting assembly 10 in the fast axis direction; the second divergence angle θ₂ is the divergence angle of the laser beam exiting from the light-emitting assembly 10 in the slow axis direction; and the third divergence angle θ₃ is the divergence angle of the laser beam passing through the first collimating sub-portion 311 in the slow axis direction. The third divergence angle θ₃ may be understood as the refraction angle of the laser beam entering the first collimating sub-portion 311.

Herein, K₁ represents a first coefficient, and K₁ is greater than or equal to 0.2 and less than or equal to 5.0 (i.e., 0.2≤K₁≤5.0). For example, K₁ is equal to 0.2, 0.9, 1.0, 1.2 or 5.0, and the first coefficient K₁ may be set according to the requirements.

It will be noted that the first coefficient K₁ is equal to a ratio of a dimension (i.e., the major axis dimension) of a beam spot in the fast axis direction to a dimension (i.e., the minor axis dimension) of the beam spot in the slow axis direction, where the beam spot is formed by the laser beam after passing through the second collimating portion 32. In a case where the first coefficient K₁ is equal to 1, it means that the beam spot has a square shape, and the major axis dimension and the minor axis dimension are equal to each other; in a case where K₁ is greater than 1, it means that the beam spot is in a shape of a rectangle with the major axis dimension greater than the minor axis dimension; in a case where K₁ is less than 1, it means that the beam spot is in a shape of a rectangle with the major axis dimension less than the minor axis dimension. If the first coefficient K₁ is less than 0.2, the major axis dimension is much less than the minor axis dimension; if the first coefficient K₁ is greater than 5.0, the major axis dimension is much greater than the minor axis dimension, which is disadvantageous to the homogenization effect and speckle reduction effect for the beam spot.

In some embodiments, the first distance D₁ is greater than or equal to 2 mm and less than or equal to 20 mm (2 mm≤D₁≤20 mm). For example, the first distance D₁ is equal to 2 mm, 4 mm, 8 mm, 15 mm or 20 mm.

If the first distance D₁ is less than 2 mm, the beam spot is too small, resulting in a decrease in the imaging quality of the projection apparatus 1. If the first distance D₁ is greater than 20 mm, the optical path is too long, so that the laser beam emitted by one light-emitting chip 11 may be incident on the first collimating sub-portion 311 and the second collimating sub-portion 321 corresponding to a light-emitting chip 11 adjacent to the one light-emitting chip 11, resulting in a decrease in the imaging quality of the projection apparatus 1, which is not conducive to the miniaturization of the light-emitting device 100. Furthermore, if the first distance D₁ is less than 2 mm, a distance between the collimating lens 30 and the light-emitting assembly 10 in the third direction Z is too small, thereby affecting the beam path direction of the laser beam; if the first distance D₁ is greater than 20 mm, the distance between the collimating lens 30 and the light-emitting assembly 10 in the third direction Z is too large, which is not conducive to the miniaturization of the light-emitting device 100.

In some embodiments, the second distance D₂ is greater than or equal to 2 mm and less than or equal to 20 mm (2 mm≤D₂≤20 mm). For example, the second distance D₂ is equal to 2 mm, 4 mm, 8 mm, 15 mm or 20 mm. If the second distance D₂ is less than 2 mm, the thickness of the collimating lens 30 is too small, resulting in an excessively small beam spot, which causes a decrease in the imaging quality of the projection apparatus 1. If the second distance D₂ is greater than 20 mm, the thickness of the collimating lens 30 is too large, which is not conducive to the miniaturization of the light-emitting device 100 and results in an excessively long optical path. As a result, the laser beam emitted by one light-emitting chip 11 may be incident on the second collimating portion 32 corresponding to a light-emitting chip 11 adjacent to the one light-emitting chip 11, resulting in a decrease in the imaging quality of the projection apparatus 1.

In some embodiments, as shown in FIG. 14, a width L₁ of the first collimating sub-portion 311 in the first direction X is greater than or equal to a product of twice the first distance D₁ and a tangent of the first divergence angle θ₁ (i.e., L₁≥2D₁×tan θ₁). In this way, a dimension of a beam spot in the first direction X is less than or equal to the width L₁ of the first collimating sub-portion 311, where the beam spot is formed by the laser beam at the first collimating sub-portion 311. As a result, a portion of the laser beam in the fast axis direction may be fully received and collimated by the first collimating sub-portion 311, thereby improving the laser utilization efficiency of the light-emitting device 100 and helping to reduce stray laser beams and bright spots caused by the stray laser beams.

In some embodiments, the width L₁ of the first collimating sub-portion 311 is greater than or equal to 1 mm and less than or equal to 20 mm (i.e., 1 mm≤L₁≤20 mm). If the width L₁ of the first collimating sub-portion 311 is less than 1 mm, it is difficult for the laser beam emitted by the light-emitting chip 11 to fully enter the first collimating sub-portion 311; if the width L₁ of the first collimating sub-portion 311 is greater than 20 mm, it is not conducive to the miniaturization of the light-emitting device 100.

In some embodiments, as shown in FIG. 15, a width L₂ of the second collimating sub-portion in the second direction Y satisfies the following formula: 2D₁×tan θ₂₊₂D₂×tan θ₃≤L₂. In this way, a dimension of a beam spot in the second direction Y is less than or equal to the width L₂ of the second collimating sub-portion 321, where the beam spot is formed by the laser beam at the second collimating sub-portion 321. As a result, a portion of the laser beam in the slow axis direction may be fully received and collimated by the second collimating sub-portion 321, thereby improving the laser utilization efficiency of the light-emitting device 100 and helping to reduce the stray laser beams and bright spots caused by the stray laser beams.

In some embodiments, the width L₂ of the second collimating sub-portion is greater than or equal to 1 mm and less than or equal to 20 mm (i.e., 1 mm≤L₂≤20 mm). If the width L₂ of the second collimating sub-portion is less than 1 mm, it is difficult for the laser beam emitted by the light-emitting chip 11 to fully enter the second collimating sub-portion 321; if the width L₂ of the second collimating sub-portion is greater than 20 mm, it is not conducive to the miniaturization of the light-emitting device 100.

In some embodiments, as shown in FIGS. 16 to 18, the shape of the beam spot exiting from the collimating lens 30 may be adjusted to obtain a square beam spot or a rectangular beam spot by adjusting a radius of curvature R₁ of the first collimating sub-portion 311 and a radius of curvature R₂ of the second collimating sub-portion 321.

In some embodiments, the radius of curvature R₁ of the first collimating sub-portion 311 satisfies the following formula: R₁/(n₁−n₂)=D₁. Herein, n₁ represents the refractive index of the collimating lens 30, and n₂ represents the refractive index of air.

In some embodiments, the radius of curvature R₂ of the second collimating sub-portion 321 satisfies the following formula: R₂/(n₁−n₂)=n₁×D₁+D₂.

In some embodiments, the radius of curvature R₁ of the first collimating sub-portion 311 is greater than or equal to 2 mm and less than or equal to 20 mm (i.e., 2 mm≤R₁≤20 mm). The radius of curvature R₂ of the second collimating sub-portion 321 is greater than or equal to 2 mm and less than or equal to 20 mm (i.e., 2 mm≤R₂≤20 mm). The radius of curvature R₂ of the second collimating sub-portion 321 is greater than the radius of curvature R₁ of the first collimating sub-portion 311 (i.e., R₂>R₁).

In some embodiments, as shown in FIG. 16, in a case where the light-emitting assembly 10 includes the first light-emitting assembly 101, the second light-emitting assembly 102 and the third light-emitting assembly 103, beam spots of three colors have the same shape and size, where the beam spots of three colors are formed by the laser beams emitted from the light-emitting assemblies 10 after passing through the collimating lens 30.

In some embodiments, for the three types of light-emitting assemblies 10, corresponding collimating lenses 30 may be used to collimate the laser beams in the fast axis direction and the slow axis direction, so as to form a variety of beam spots with different shapes and sizes.

In some embodiments, in a case where white beams exiting from the light-emitting device 100 serve as a laser source, it is necessary to mix the red laser beam, green laser beam, and blue laser beam exiting from the light-emitting assemblies 10 in the same proportion. However, due to the performance differences among light-emitting chips emitting laser beams of different colors, as shown in FIG. 5E, the light-emitting device 100 includes more red light-emitting chips 1110 than green light-emitting chips 112 and blue light-emitting chips 113. Accordingly, the number of red beam spots is greater than the number of blue beam spots or green beam spots.

In some embodiments, as shown in FIG. 18, the laser beam emitted by the first light-emitting assembly 101 forms a first beam spot 51 (e.g., a red beam spot), the laser beam emitted by the second light-emitting assembly 102 forms a second beam spot 52 (e.g., a blue beam spot), and the laser beam emitted by the third light-emitting assembly 103 forms a third beam spot 53 (e.g., a green beam spot). The number of first beam spots 51 is greater than the number of second beam spots 52 and the number of third beam spots 53. A dimension of the first beam spot 51 in the fast axis direction is greater than a dimension of the first beam spot 51 in the slow axis direction by reducing a dimension of the first beam spot 51 in the row direction (i.e., the slow axis direction) and making a dimension of the first beam spot 51 in the column direction (i.e., the fast axis direction) equal to a dimension of the second beam spot 52 or the third beam spot 53 in the column direction.

For example, a first sub-distance D₁₁ is defined as an optical path from the first light-emitting assembly 101 to the first collimating sub-portion 311, and a first sub-thickness D₂₁ is defined as a thickness of a collimating lens 30 corresponding to the first light-emitting assembly 101. The first sub-distance D₁₁ and the first sub-thickness D₂₁ satisfy the following formula: D₁₁×tan θ₁=K₂×(D₁₁×tan θ₂+D₂₁×tan θ₃). Herein, K₂ is a second coefficient. The second coefficient K₂ is greater than 1.0 and less than or equal to 5.0 (i.e., 1.0<K₂≤5.0). In this way, the dimension of the first beam spot 51 in the fast axis direction may be greater than the dimension of the first beam spot 51 in the slow axis direction.

A second sub-distance D₁₂ is defined as an optical path from the second light-emitting assembly 102 to the first collimating sub-portion 311, and a second sub-thickness D₂₂ is defined as a thickness of a collimating lens 30 corresponding to the second light-emitting assembly 102. The second sub-distance D₁₂ and the second sub-thickness D₂₂ satisfy the following formula: D₁₂×tan θ₁=K₁×(D₁₂×tan θ₂+D₂₂×tan θ₃).

A third sub-distance D₁₃ is defined as an optical path from the third light-emitting assembly 103 to the first collimating sub-portion 311, and a third sub-thickness D₂₃ is defined as a thickness of a collimating lens 30 corresponding to the third light-emitting assembly 103. The third sub-distance D₁₃ and the third sub-thickness D₂₃ satisfy the following formula: D₁₃×tan θ₁=K₁×(D₁₃×tan θ₂+D₂₃×tan θ₃).

The second coefficient K₂ is greater than the first coefficients K₁ (i.e., K₂>K₁) corresponding to the second light-emitting assembly 102 and the third light-emitting assembly 103. In this way, it is possible to ensure that the dimension of the first beam spot 51 in the column direction is equal to the dimension of at least one of the second beam spot 52 or the third beam spot 53 in the column direction.

In some embodiments, as shown in FIG. 17, the number of first beam spots 51 is greater than the number of second beam spots 52 and the number of third beam spots 53. A dimension of the first beam spot 51 in the fast axis direction is less than a dimension of the first beam spot 51 in the slow axis direction by reducing a dimension of the first beam spot 51 in the column direction and making a dimension of the first beam spot 51 in the row direction equal to a dimension of the second beam spot 52 (or the third beam spot 53) in the row direction.

In some embodiments, the first sub-distance D₁₁ and the first sub-thickness D₂₁ satisfy the following formula: D₁₁×tan θ₁=K₃×(D₁₁×tan θ₂+D₂₁×tan θ₃). Herein, K₃ is a third coefficient. The third coefficient K₃ is greater than 0.2 and less than or equal to 1.0 (i.e., 0.2<K₃≤1.0). In this way, the dimension of the first beam spot 51 in the fast axis direction may be less than the dimension of the first beam spot 51 in the slow axis direction.

The second sub-distance D₁₂ and the second sub-thickness D₂₂ satisfy the following formula: D₁₂×tan θ₁=K₁×(D₁₂×tan θ₂+D₂₂×tan θ₃). The third sub-distance D₁₃ and the third sub-thickness D₂₃ satisfy the following formula: D₁₃×tan θ₁=K₁×(D₁₃×tan θ₂+D₂₃×tan θ₃).

The third coefficient K₃ is less than the first coefficients K₁ (i.e., K₁>K₃) corresponding to the second light-emitting assembly 102 and the third light-emitting assembly 103. In this way, it is possible to ensure that the dimension of the first beam spot 51 in the row direction is equal to the dimension of at least one of the second beam spot 52 or the third beam spot 53 in the row direction.

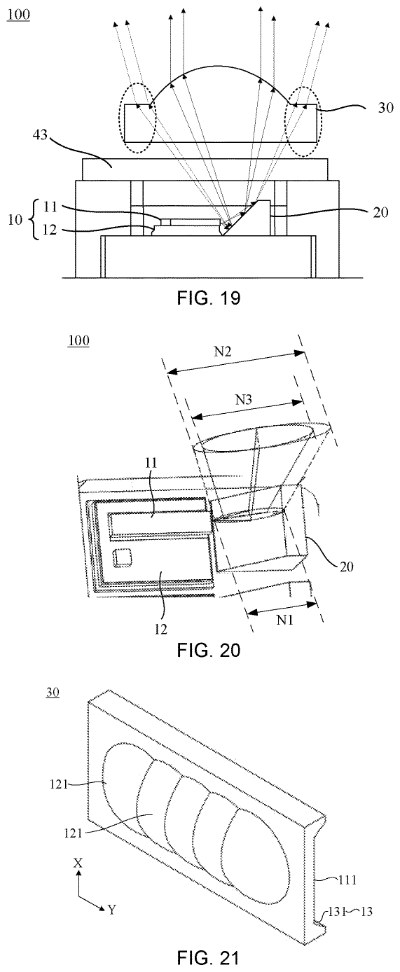

As shown in FIG. 19, since the laser beam emitted by the light-emitting assembly 10 has a large divergence angle in the fast axis direction, as the optical path of the propagating laser beam increases, the size of the beam spot increases. The laser beam forms a beam spot with a large size after being reflected by the reflecting lens 20 and passing through the cover plate 43. In this way, a portion of the laser beam will exceed the collimation region, and a region beyond the collimation region corresponds to the region marked by the elliptical dashed line in FIG. 19. The laser beam in this region is difficult to be collimated by the collimating lens 30, and eventually becomes a stray laser beam.

As shown in FIG. 20, a dimension (e.g., a dimension of a major axis of the elliptical beam spot) of a beam spot formed by the laser beam emitted by the light-emitting assembly 10 at the reflecting surface of the reflecting lens 20 is a first length N1. A dimension of the beam spot after being reflected by the reflecting lens 20 is a second length N2. Since a portion of the laser beam reflected by the reflecting surface cannot be utilized by the collimating lens 30, a dimension of the beam spot capable of being collimated by the collimating lens 30 is only a third length N3, and the remaining portion of the laser beam is not utilized and becomes the stray laser beam. The third length N3 is less than the second length N2.

To this end, the collimating lens in some embodiments of the present disclosure may further include the following structures.

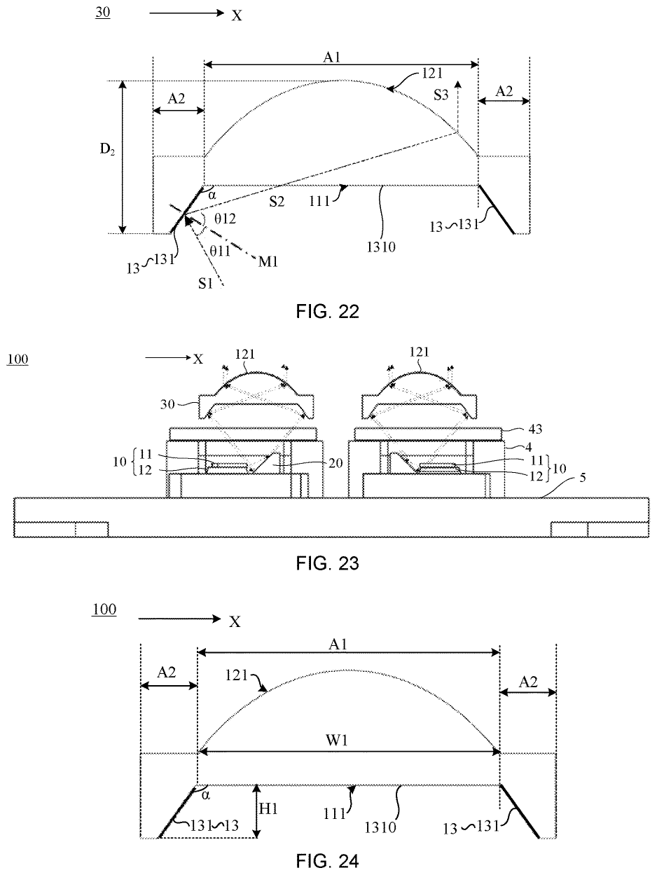

In some embodiments, as shown in FIGS. 21 to 23, the collimating lens 30 includes a first region A1 and a second region A2. The first region A1 and the second region A2 are arranged along the first direction X. The second region A2 is located on at least one side of the first region A1. For example, the second region A2 is located only on a side of the first region A1; alternatively, as shown in FIGS. 22, 24 and 25, the second regions A2 are located on two sides of the first region A1.

It will be noted that the laser beams emitted by the light-emitting assembly 10 have a certain divergence angle. A laser beam with a small divergence angle may be incident on the first region A1, while a laser beam with a large divergence angle is incident on the second region A2. Laser beams with a divergence angle greater than or equal to a preset value may be referred to as laser beams with a large divergence angle, and laser beams with a divergence angle less than a preset value may be referred to as laser beams with a small divergence angle.

For example, in an example where the divergence angles of the laser beams emitted by the light-emitting assembly 10 are less than or equal to 35°, the laser beams with a divergence angle less than 30° may be incident on the first region A1 and these laser beams may be collimated by the collimating lens 30, while the laser beams with a divergence angle within a range of 30° to 35° are incident on the second region A2 and these laser beams may be understood as the stray laser beams.

As shown in FIGS. 21 and 22, the collimating lens 30 further includes a beam path adjusting component 13. The beam path adjusting component 13 is located in the second region A2. The beam path adjusting component 13 is configured to adjust a beam path of a laser beam incident on the second region A2. By providing the beam path adjusting component 13, the laser beam after the beam path adjustment may be incident on the first region A1 and collimated by the collimating lens 30, so that the laser beam becomes the collimated beam, thereby improving the laser energy utilization efficiency of the light-emitting device 100. In addition, it is also possible to improve the image quality and contrast of the projection apparatus 1, and help reduce the heat generated by the projection apparatus 1.

It will be noted that the manner in which the beam path adjusting component 13 adjusts the beam path includes reflection and scattering. In some examples, the beam path adjusting component 13 has a high reflectivity and a low refractive index for the incident laser beam. For example, the reflectivity is greater than or equal to 80%, so as to reflect the laser beam. In some other examples, the beam path adjusting component 13 includes a reflective surface or a scattering surface. For example, the beam path adjusting component 13 includes a total reflection surface. Of course, the beam path adjusting component 13 may also adjust the beam path in other manners, and the present disclosure is not limited thereto.

In some embodiments, as shown in FIGS. 21 to 23, the collimating lens 30 further includes at least one target curved surface 121. The target curved surface 121 is a surface of the collimating lens 30 away from a laser-incident surface 111 (i.e. a surface of the collimating lens 30 proximate to the light-emitting assembly 10) of the collimating lens 30, and is located in the first region A1. The target curved surface 121 protrudes in a direction away from the laser-incident surface 111. The target curved surface 121 may be an aspherical surface or a free-form curved surface. The target curved surface 121 compresses and collimates the laser beams emitted by the corresponding light-emitting assembly 10 in the first direction X, to reduce the divergence angle of the laser beams in the first direction X. The target curved surface 121 is disposed corresponding to the first region A1, and the second region A2 is located on at least one side of the target curved surface 121 in the first direction X. The stray laser beam in the first direction X from the light-emitting assembly 10 is reflected by the beam path adjusting component 13, the beam path adjusting component 13 adjusts the beam path of the stray laser beam, so that the stray laser beam after the beam path adjustment may be incident on the first region A1 and becomes the collimated beam after being collimated by the target curved surface 121, thereby improving the laser energy utilization efficiency of the light-emitting device 100.

In some embodiments, a thickness (i.e., the thickness H3 hereinafter) of the target curved surface is greater than or equal to 0.8 mm and less than or equal to 1.1 mm.

As shown in FIGS. 24 to 26, the target curved surface 121 protrudes in the direction away from the light-emitting assembly 10. Of course, the target curved surface 121 may also protrude in a direction proximate to the light-emitting assembly 10.

In some embodiments, as shown in FIGS. 21 and 23, in a case where the light-emitting device 100 includes a plurality of light-emitting assemblies 10 and a plurality of target curved surfaces 121, the plurality of target curved surfaces 121 correspond to the plurality of light-emitting assemblies 10, and a direction in which the plurality of target curved surfaces 121 are arranged is the same as a direction in which the light-emitting assemblies 10 are arranged. The plurality of target curved surfaces 121 and the plurality of light-emitting assemblies 10 are all arranged along the second direction Y. It will be noted that the plurality of light-emitting assemblies 10 may be arranged in an array on the base plate 5, and the light-emitting assembly 10 emits the laser beam(s) along the first direction X.

In some embodiments, as shown in FIGS. 21, 22 and 24, the beam path adjusting component 13 includes a first adjusting sub-component 131. The first adjusting sub-component 131 is configured to adjust a beam path of a laser beam incident on the first adjusting sub-component 131. For example, the collimating lens 30 further includes a groove 1310. A side of the collimating lens 30 facing the light-emitting assembly 10 is recessed in the direction away from the light-emitting assembly 10, to form the groove 1310. The groove 1310 includes a bottom surface and a side wall. The bottom surface of the groove 1310 is the laser-incident surface 111 of the collimating lens 30 and is located in the first region A1. In the first direction X, a dimension of the laser-incident surface 111 is the same as a dimension of the first region A1. The side wall of the groove 1310 serves as the first adjusting sub-component 131.

Among the laser beams emitted by the light-emitting assembly 10, a laser beam with a small divergence angle is directly incident on the laser-incident surface 111 (that is, the laser beam with a small divergence angle is incident on the first region A1). The laser beam enters an interior of the collimating lens 30 after passing through the laser-incident surface 111, and the laser beam exits from the collimating lens 30 after being collimated by the target curved surface 121. A laser beam with a large divergence angle is incident on the first adjusting sub-component 131 (i.e., the laser beam with a large divergence angle is incident on the second region A2). The first adjusting sub-component 131 adjusts the beam path of the laser beam, so that the laser beam after the beam path adjustment may be incident on the laser-incident surface 111 and enter the interior of the collimating lens 30. The laser beam becomes the collimated beam after being collimated by the target curved surface 121, thereby improving the laser energy utilization efficiency of the light-emitting device 100.

In some embodiments, the side wall of the groove 1310 is coated with a reflective film, so as to form a first adjusting sub-component 131. In this case, the first adjusting sub-component 131 is an external reflection surface. The first adjusting sub-component 131 reflects the laser beam incident on the first adjusting sub-component 131. Alternatively, at least a portion of the side wall of the groove 1310 is recessed and at least a portion of the side wall protrudes, so as to form a concave-convex microstructure, thereby forming the first adjusting sub-component 131. In this way, the first adjusting sub-component 131 may reflect and scatter the laser beam incident on the first adjusting sub-component 131.

FIG. 22 shows a process of handling the stray laser beam by the collimating lens 30. As shown in FIG. 22, M1 represents a normal of the first adjusting sub-component 131, S1 represents a stray laser beam, S2 represents a laser beam reflected by the first adjusting sub-component 131, S3 represents a collimated beam, θ₁₁ represents an incident angle, and θ₁₂ represents a reflection angle. The first adjusting sub-component 131 is an external reflection surface. The stray laser beam S1 incident on the first adjusting sub-component 131 is reflected by the first adjusting sub-component 131. The reflected laser beam S2 passes through the laser-incident surface 111 and is incident on the target curved surface 121. The reflected laser beam S2 becomes the collimated beam S3 after being collimated by the target curved surface 121.

It will be noted that, in order to clearly illustrate the optical path of the stray laser beam in the light-emitting device 100, FIG. 22 only shows the stray laser beam incident on the first adjusting sub-component 131, and omits the laser beam directly incident on the laser-incident surface 111. It may be understood that the collimating lens 30 will also collimate the laser beam directly incident on the laser-incident surface 111.

In some embodiments, as shown in FIGS. 22 and 24, a first angle α between the first adjusting sub-component 131 and the laser-incident surface 111 is greater than or equal to 110° and less than or equal to 140° (i.e., 110°≤α≤) 140°. It may also be understood that an angle between the first adjusting sub-component 131 and the thickness direction of the collimating lens 30 is greater than or equal to 40° and less than or equal to 70°.

If the first angle α is less than 110° or greater than 140°, it is likely that some stray laser beams are unable to be incident on the target curved surface 121, and thus cannot become the collimated beam, thereby reducing the laser energy utilization efficiency of the light-emitting device 100.

In some embodiments, the thickness D₂ (also referred to as the second distance) of the collimating lens 30 is greater than or equal to 1.5 mm and less than or equal to 2.5 mm. As shown in FIG. 24, in the thickness direction of the collimating lens 30, a depth H1 of the groove 1310 is greater than or equal to 0.5 mm and less than or equal to 0.7 mm (i.e., 0.5 mm≤H1≤0.7 mm). In this way, the collimating lens 30 may receive a large number of laser beams exiting from the light-emitting assembly 10, and the strength of the collimating lens 30 may be increased.

If the depth H1 of the groove is less than 0.5 mm, the beam path of the laser beam is affected and the collimation effect of the collimating lens 30 is reduced; if the depth H1 of the groove is greater than 0.7 mm, the strength of the collimating lens 30 is low, and it is not conducive to the miniaturization of the light-emitting device 100.

Since the laser beam continuously diverges before being incident on the collimating lens 30, the size of the beam spot increases as the propagation distance of the laser beam increases. A width (e.g., a dimension of the laser-incident surface 111 in the first direction X) of the laser-incident surface 111 is related to the optical path of the laser beam. A third distance is defined as a propagation distance of the laser beam from the laser-exit side of the light-emitting assembly 10 to the laser-incident surface 111 of the collimating lens 30. The third distance may be understood as the optical path. The third distance is greater than or equal to 1.9 mm and less than or equal to 2.2 mm. In the case of this optical path, the width of the laser-incident surface 111 in the first direction X is greater than or equal to 3.0 mm and less than or equal to 3.4 mm. In this way, it is conducive to the miniaturization of the light-emitting device 100 by reducing the third distance as much as possible.

If the third distance is less than 1.9 mm, the optical path of the laser beam is too short, resulting in an excessively small beam spot, which causes a decrease in the imaging quality of the projection apparatus 1. If the third distance is greater than 2.2 mm, the optical path of the laser beam is too long, which is not conducive to the miniaturization of the light-emitting device 100, and results in an excessively long optical path. As a result, the laser beam emitted by one light-emitting chip 11 may be incident on the collimating lens 30 corresponding to a light-emitting chip 11 adjacent to the one light-emitting chip 11, resulting in a decrease in the imaging quality of the projection apparatus 1.

In some embodiments, as shown in FIG. 24, the target curved surface 121 is disposed opposite to the laser-incident surface 111, and a width of the target curved surface 121 is the same as the width of the laser-incident surface 111. The width W1 of the target curved surface 121 in the first direction X is greater than or equal to 3.0 mm and less than or equal to 3.4 mm (i.e., 3.0 mm≤W1≤3.4 mm). It will be noted that, in the first direction X, a distance between two end edges of the target curved surface 121 is the width W1 of the target curved surface 121.

In some embodiments, the width of the target curved surface 121 is less than the width of the laser-incident surface 111. In this way, it is conducive to the miniaturization of the light-emitting device 100 while ensuring that the target curved surface 121 can collimate the laser beam. For example, the width of the laser-incident surface 111 is 3.2 mm, and the width of the target curved surface 121 is 3.0 mm. For another example, the width of the laser-incident surface 111 is 3.0 mm, and the width of the target curved surface 121 is 2.8 mm. For another example, the width of the laser-incident surface 111 is 3.6 mm, and the width of the target curved surface 121 is 3.4 mm.

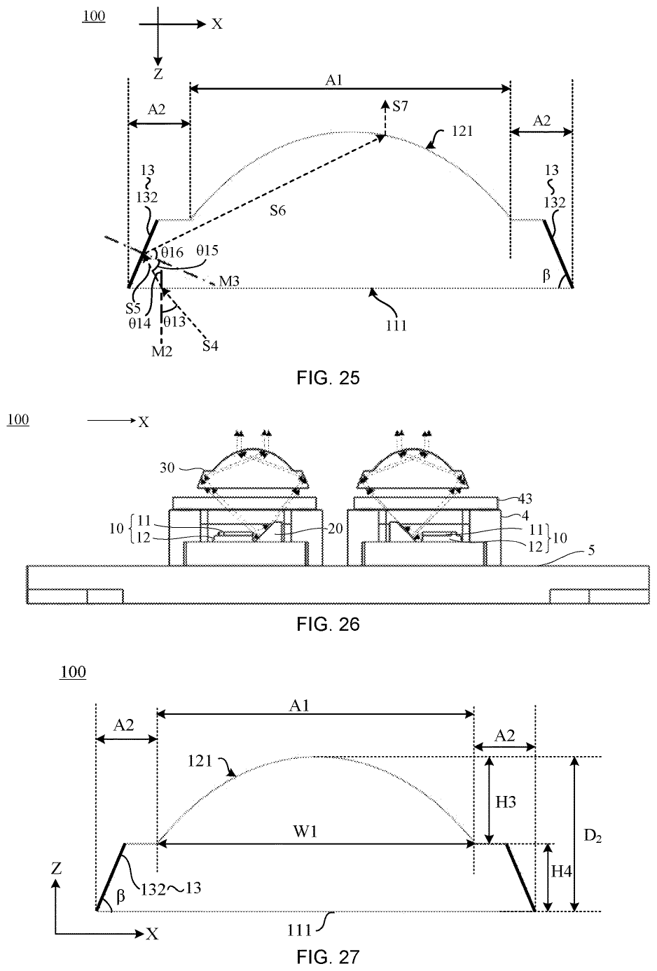

In some embodiments, as shown in FIGS. 25 and 26, the beam path adjusting component 13 includes a second adjusting sub-component 132. For example, the laser-incident surface 111 of the collimating lens 30 is located in the first region A1 and the second region A2. The second adjusting sub-component 132 is a side wall of the collimating lens 30 in the first direction X and is configured to adjust the beam path of the laser beam incident on the second region A2, so that the laser beam after the beam path adjustment may be incident on the first region A1.

The laser beams emitted by the light-emitting assembly 10 enter the interior of the collimating lens 30 after passing through the laser-incident surface 111. The laser beam incident on the first region A1 may be collimated by the target curved surface 121. The laser beam incident on the second region A2 is reflected by the second adjusting sub-component 132 to the first region A1, and then collimated by the target curved surface 121.

In the laser beams emitted by the light-emitting assembly 10, a laser beam with a small divergence angle is directly incident on the laser-incident surface 111 in the first region A1. The laser beam enters the interior of the collimating lens 30 after passing through the laser-incident surface 111, and then the laser beam exits from the collimating lens 30 after being collimated by the target curved surface 121. A laser beam with a large divergence angle is incident on the laser-incident surface 111 located in the second region A2. The laser beam enters the interior of the collimating lens 30 and is incident on the second adjusting sub-component 132 after passing through the laser-incident surface 111. The second adjusting sub-component 132 adjusts the beam path of the laser beam incident on the second adjusting sub-component 132, so that the laser beam after the beam path adjustment is incident on the target curved surface 121 located in the first region A1, and becomes the collimated beam after being collimated by the target curved surface 121, thereby improving the laser energy utilization efficiency of the light-emitting device 100.

FIG. 25 shows a process of handling the stray laser beam by the collimating lens 30. Herein, M2 represents a normal of the laser-incident surface 111, M3 represents a normal of the second adjusting sub-component 132, S4 represents a stray laser beam, S5 represents a laser beam incident from the laser-incident surface 111, S6 represents a laser beam reflected by the second adjusting sub-component 132, S7 represents a collimated beam, θ13 represents an incident angle of the stray laser beam at the laser-incident surface 111, θ14 represents a refraction angle of the stray laser beam at the laser-incident surface 111, θ15 represents an incident angle of the stray laser beam at the second adjusting sub-component 132, and θ16 represents a reflection angle of the stray laser beam at the second adjusting sub-component 132. The second adjusting sub-component 132 is an internal reflection surface. The stray laser beam S4 incident on the laser-incident surface 111 in the second region A2 is refracted at the laser-incident surface 111 and enters the interior of the collimating lens 30. The laser beam S5 (i.e., the stray laser beam S4 after refraction) is incident on the second adjusting sub-component 132 and is reflected. The reflected laser beam S6 (i.e. the reflected laser beam S5) is incident on the target curved surface 121 in the first region A1, and becomes the collimated beam S7 after being collimated by the target curved surface 121.

It will be noted that, in order to clearly illustrate the optical path of the stray laser beam in the light-emitting device 100, FIG. 25 only shows the stray laser beam at the laser-incident surface 111 in the second region A2, and omits the laser beam directly incident on the laser-incident surface 111 in the first region A1. The collimating lens 30 will also collimate the laser beam incident on the laser-incident surface 111 in the first region A1.

In some embodiments, as shown in FIGS. 25 and 27, a second angle β between the second adjusting sub-component 132 and the laser-incident surface 111 is greater than or equal to 40° and less than or equal to 50° (i.e., 40°≤β≤) 50°. In this way, as many stray laser beams as possible may be incident on the target curved surface 121, so that the stray laser beams may be collimated by the target curved surface 121.

If the second angle β is less than 40° or greater than 50°, the stray laser beams incident on the target curved surface 121 are reduced, thereby reducing the laser energy utilization efficiency of the light-emitting device 100.

In some embodiments, as shown in FIG. 27, a perpendicular distance (i.e., a distance in the third direction Z) between the laser-incident surface 111 and a vertex (i.e., the highest point) of the target curved surface 121 is the thickness of the collimating lens 30, and the thickness is the second distance D₂. The second distance D₂ is greater than or equal to 1.5 mm and less than or equal to 2.0 mm (i.e., 1.5 mm≤D₂≤2.0 mm). If the second distance D₂ is less than 1.5 mm, the thickness of the collimating lens 30 is too small, resulting in a small beam spot, which in turn causes a decrease in the imaging quality of the projection apparatus 1. If the second distance D₂ is greater than 2.0 mm, the thickness of the collimating lens 30 is too large, which is not conducive to the miniaturization of the light-emitting device 100 and results in an excessively long optical path. As a result, the laser beam emitted by one light-emitting chip 11 may be incident on the collimating lens 30 corresponding to a light-emitting chip 11 adjacent to the one light-emitting chip 11, resulting in a decrease in the imaging quality of the projection apparatus 1.

A perpendicular distance between the vertex of the target curved surface 121 and the lowest point of the target curved surface 121 is a thickness H3 of the target curved surface 121. The thickness H3 of the target curved surface 121 is greater than or equal to 0.8 mm and less than or equal to 1.1 mm (i.e., 0.8 mm≤H3≤1.1 mm). If the thickness H3 of the target curved surface 121 is less than 0.8 mm, the thickness of the target curved surface 121 is too small, so that the target curved surface 121 has a poor collimation effect on the laser beam; if the thickness H3 of the target curved surface 121 is greater than 1.1 mm, the thickness of the target curved surface 121 is too large, the optical path of the laser beam is too long, which is not conducive to the miniaturization of the light-emitting device 100.

A perpendicular distance between the lowest point of the target curved surface 121 and the laser-incident surface 111 is a fourth distance H4 (i.e. the minimum distance between the target curved surface 121 and the laser-incident surface 111). The fourth distance H4 is greater than or equal to 0.7 mm and less than or equal to 0.9 mm (i.e., 0.7 mm≤H4≤0.9 mm). It will be noted that, in a case where the second distance D₂ and the thickness H3 of the target curved surface 121 are determined, a value range of the fourth distance H4 is determined.

It will be noted that the width of the laser-incident surface 111 is greater than the width of the target curved surface 121.

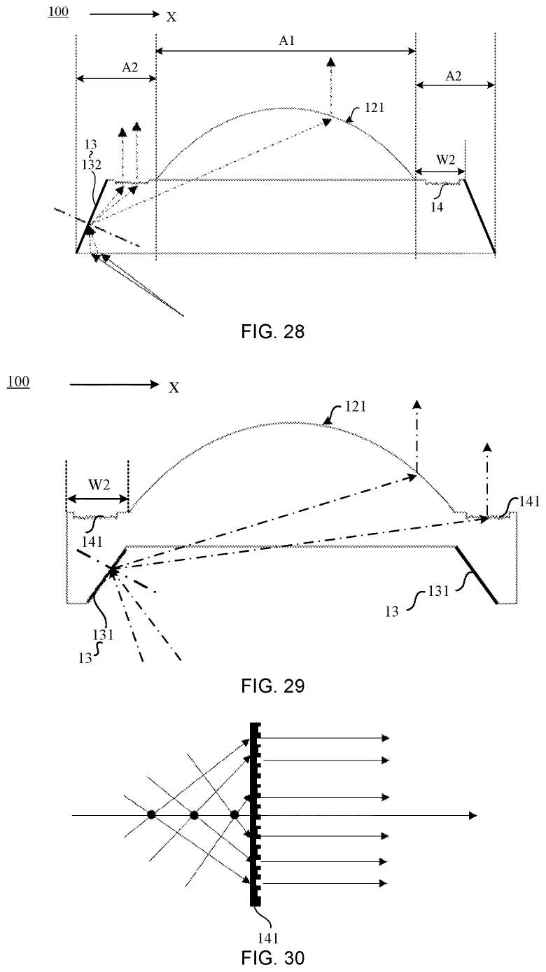

In some embodiments, as shown in FIGS. 28 and 29, the collimating lens 30 further includes a first collimating surface 14 (e.g., a microstructure surface). The first collimating surface 14 is located on a side of the collimating lens 30 away from the light-emitting assembly 10 and in the second region A2. The first collimating surface 14 is configured to collimate the laser beam incident on the first collimating surface 14. For example, the microstructure surface is a portion of a surface of the collimating lens 30 away from the plurality of light-emitting chips and is located in the second region A2.

Due to manufacturing errors, the parameters of the collimating lens 30 may exceed the design range, causing some stray laser beams, after the beam path of the stray laser beams is adjusted by the beam path adjusting component 13, to be incident on a position outside the target curved surface 121. For example, some stray laser beams after being reflected by the first adjusting sub-component 131 or the second adjusting sub-component 132 may be incident on the second region A2 on the other side. Therefore, these stray laser beams may be collimated by the first collimating surface 14 by providing the first collimating surface 14 on the side of the collimating lens 30 away from the light-emitting assembly 10 and in the second region A2.

In some embodiments, as shown in FIGS. 28 and 29, a width W2 of the first collimating surface 14 in the first direction X is greater than or equal to 0.3 mm and less than or equal to 0.4 mm (i.e., 0.3 mm≤W2≤0.4 mm). If the width W2 of the first collimating surface 14 is less than 0.3 mm, a large number of stray laser beams cannot be incident on the first collimating surface 14, resulting in light loss, thereby causing a poor collimation effect of the first collimating surface 14 on the stray laser beams; if the width W2 of the first collimating surface 14 is greater than 0.4 mm, the size of the target curved surface 121 is reduced, which is not conducive to the collimation effect of the target curved surface 121 on the stray laser beams.

In some embodiments, as shown in FIG. 30, the first collimating surface 14 includes a diffractive optical element (DOE) 141. The diffractive optical element 141 has an uneven surface, and the surface of the diffractive optical element 141 may be configured according to parameters such as the wavelength, beam quality, and near-field light intensity distribution of the laser beam. The diffractive optical element 141 modulates the phase of the stray laser beam. When the stray laser beam passes through the diffractive optical element 141, the diffractive optical element 141 enables the stray laser beam to form the collimated beam at a predetermined distance. The processing effect of the diffractive optical element 141 on the stray laser beam is shown in FIG. 30.

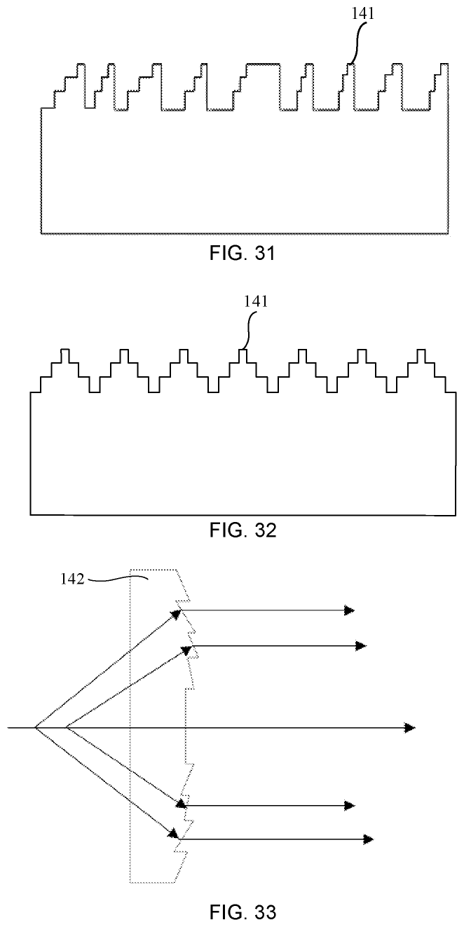

In some embodiments, as shown in FIGS. 31 and 32, a surface of the diffractive optical element 141 is provided with a relief structure. A relief is formed on a side of the diffractive optical element 141 facing away from the laser-incident surface 111 by means of etching, and a depth of the relief is at a submicron level.

It will be noted that FIGS. 31 and 32 illustrate by considering an example in which the relief on the diffractive optical element 141 is in the shape of a rectangular step. Of course, in some embodiments, the relief may also be configured in other shapes, such as a semi-circular step or a triangular step. The collimation effect of the diffractive optical element 141 on the stray laser beams may be improved by means of the relief structure on the surface of the diffractive optical element 141.

It will be noted that reliefs of different shapes may be configured according to parameters such as the wavelength, beam quality, and near-field light intensity distribution of the laser beam.

In some embodiments, as shown in FIG. 33, the first collimating surface 14 includes a Fresnel structure surface 142. The Fresnel structure surface 142 is similar to a Fresnel lens. The Fresnel structure surface 142 is formed on a side of collimating lens 30 facing away from the light-emitting assembly 10 and located in the second region A2 by means of etching. The Fresnel structure surface 142 includes a plurality of grooves. Inclination angles of the grooves are different from one another. Each groove may be regarded as an independent small lens. Stray laser beams with a predetermined divergence angle may be corrected into parallel laser beams after passing through the Fresnel structure surface 142. The Fresnel structure surface 142 performs collimation processing on the stray laser beams by using the refraction principle of light, and the Fresnel structure surface 142 in the second region A2 uses its profiles with different angles as refractive surfaces, so as to achieve collimation for the stray laser beams.

It will be noted that “the inclination angle of the groove” may refer to an angle between an inclined surface of the groove and a plane where the collimating lens 30 is located.

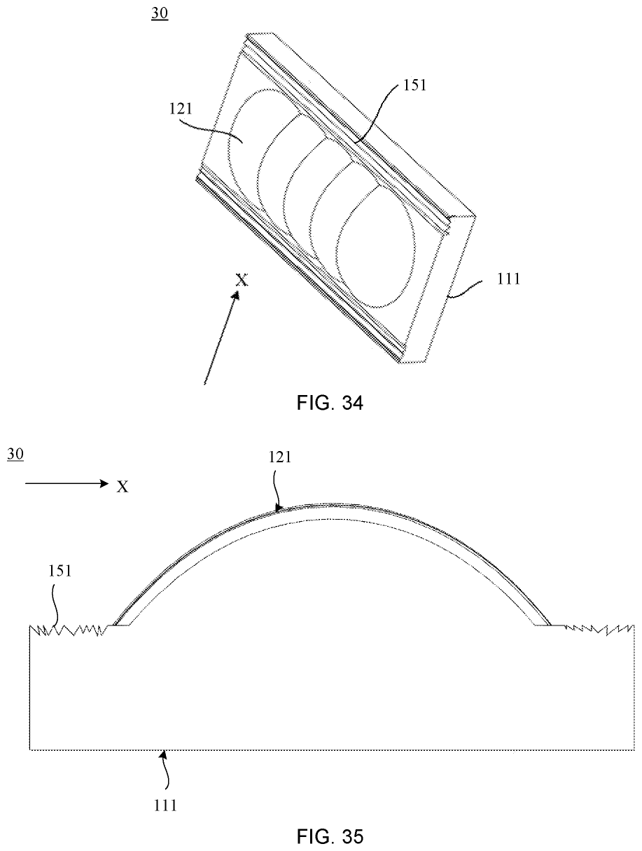

In some embodiments, as shown in FIGS. 34 and 35, the collimating lens 30 further includes a second collimating surface 151. The second collimating surface 151 is disposed on the side of the collimating lens 30 facing away from the light-emitting assembly 10, and is located in the second region A2. The second collimating surface 151 is configured to collimate stray laser beams incident on the second region A2. In this case, the beam path adjusting component 13 may be omitted.

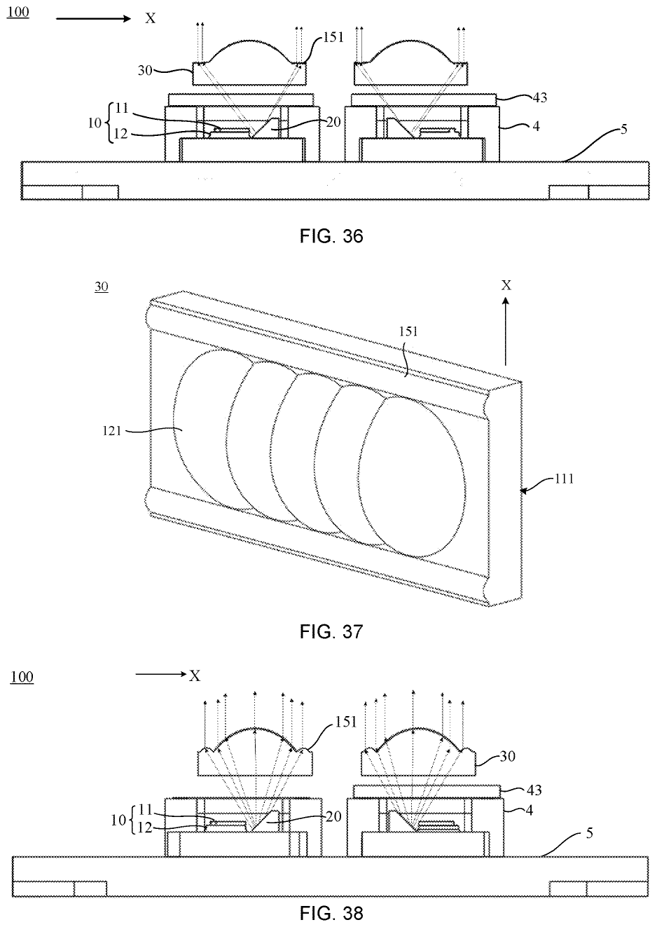

For example, as shown in FIGS. 36 to 38, in the collimating lens 30, the second collimating surface 151 collimates the laser beam incident on the second region A2, making the laser beam a collimated beam, which is conducive to improving the laser energy utilization efficiency of the light-emitting device 100. In this way, in a case where the size of the collimating lens 30 remains basically unchanged, second collimating surfaces 151 may collimate the stray laser beams not covered by the target curved surface 121 by adding the second collimating surfaces 151 on two sides of the target curved surface 121, so as to collimate these stray laser beams into usable beams, thereby improving the laser energy utilization efficiency of the light-emitting device 100. In addition, the optical path of the laser beam remains unchanged, and only a thickness of the second collimating surface 151 changes.

In some embodiments, the second collimating surface 151 includes a multi-focal curved surface. The collimation efficiency of the second collimating surface 151 for the stray laser beams is improved by using the multi-focal curved surface to collimate the stray laser beams, which is conducive to improving the laser energy utilization efficiency of the light-emitting device 100. For example, the multi-focal free-form curved surface includes the Fresnel structure surface.

For example, the second collimating surface 151 is the Fresnel structure surface. The Fresnel structure surface collimates the incident stray laser beams, so that these stray laser beams become the collimated beam, thereby improving the laser energy utilization efficiency of the light-emitting device 100.

It will be noted that any one of the disclosed technical solutions in the present disclosure may, to a certain extent, solve one or more of the technical problems described above and achieve the corresponding technical effects. Alternatively, a plurality of disclosed technical solutions may also be combined into an overall solution, so as to solve one or more of the technical problems described above and achieve the corresponding technical effects. Alternatively, some disclosed technical solutions may also be combined into an overall solution, and in combination with the related art and deteriorated solutions, but the solution may compensate the deterioration trend by adopting the technical means in the present disclosure, thereby, as a whole, solving one or more of the technical problems described above to a certain extent and achieving the corresponding technical effects. Alternatively, each of the disclosed technical solutions is combined into a complete technical solution, constituting an organic and indivisible overall solution, thereby solving the technical problems as a whole and achieves the corresponding technical effects.

Any disclosed technical solution in the present disclosure and the recombination of the plurality of disclosed technical solutions each may form a complete technical solution and solve one or more of the technical problems described above and achieve the corresponding technical effects. They all belong to the content of the present disclosure and belong to the content that is directly and unambiguously determined according to the content of the present disclosure.

A person skilled in the art will understand that the scope of disclosure in the present disclosure is not limited to specific embodiments described above and may modify and substitute some elements of the embodiments without departing from the spirits of the present disclosure. The scope of the present disclosure is limited by the appended claims.

What is claimed is:

1. A light-emitting device, comprising:
a plurality of light-emitting chips, configured to emit laser beams; and
a collimating lens, located on laser-exit sides of the plurality of light-emitting chips, the collimating lens being configured to receive the laser beams from the plurality of light-emitting chips and collimate the incident laser beams, and the collimating lens including:
a first collimating portion, the first collimating portion being a surface of the collimating lens facing the plurality of light-emitting chips, the first collimating portion being configured to: collimate an incident laser beam in a first direction and reduce a divergence angle of the incident laser beam in a second direction, such that a divergence angle of a laser beam exiting from the first collimating portion in the first direction is reduced to 0°, a divergence angle of the laser beam exiting from the first collimating portion in the second direction is reduced, and the divergence angle of the laser beam exiting from the first collimating portion in the second direction is greater than 0°; wherein a divergence angle of the laser beam incident on the first collimating portion in the first direction is greater than a divergence angle of the laser beam incident on the first collimating portion in the second direction, the first direction is parallel to a fast axis direction of the laser beam incident on the first collimating portion, the second direction is parallel to a slow axis direction of the laser beam incident on the first collimating portion, and the first direction is perpendicular to the second direction; and
a second collimating portion, the second collimating portion being a surface of the collimating lens away from the plurality of light-emitting chips, the second collimating portion and the first collimating portion being arranged at an interval, and the second collimating portion being configured to: collimate an incident laser beam in the second direction, such that a divergence angle of a laser beam exiting from the second collimating portion in the first direction remains unchanged, and a divergence angle of the laser beam exiting from the second collimating portion in the second direction is reduced to 0°;
wherein a change amount between a divergence angle of the laser beam incident on the second collimating portion in the second direction and the divergence angle of the laser beam exiting from the second collimating portion in the second direction is greater than a change amount between the divergence angle of the laser beam incident on the first collimating portion in the second direction and the divergence angle of the laser beam exiting from the first collimating portion in the second direction.

2. The light-emitting device according to claim 1, further comprising:
a reflecting lens, disposed on the laser-exit sides of the plurality of light-emitting chips and configured to reflect the laser beams emitted by the plurality of light-emitting chips to the collimating lens; wherein the collimating lens and the reflecting lens are arranged along a third direction; the third direction is perpendicular to the first direction and the second direction; the plurality of light-emitting chips are arranged in an array along the first direction and the second direction;
wherein the first collimating portion includes a plurality of first collimating sub-portions; the plurality of first collimating sub-portions are arranged along the first direction, each of the plurality of first collimating sub-portions extends along the second direction, and any one of the plurality of first collimating sub-portions corresponds to a row of light-emitting chips arranged along the second direction among the plurality of light-emitting chips; and
the second collimating portion includes a plurality of second collimating sub-portions; the plurality of second collimating sub-portions are arranged along the second direction, each of the plurality of second collimating sub-portions extends along the first direction, and any one of the plurality of second collimating sub-portions corresponds to a row of light-emitting chips arranged along the first direction among the plurality of light-emitting chips.

3. The light-emitting device according to claim 2, wherein an orthogonal projection of the first collimating sub-portion on a plane formed by the first direction and the third direction is a curve; and an orthogonal projection of the first collimating sub-portion on a plane formed by the second direction and the third direction is a straight line; and
an orthogonal projection of the second collimating sub-portion on the plane formed by the first direction and the third direction is a straight line; and an orthogonal projection of the second collimating sub-portion on the plane formed by the second direction and the third direction is a curve.

4. The light-emitting device according to claim 2, wherein an optical path between any one of the plurality of light-emitting chips and a corresponding first collimating sub-portion of the plurality of first collimating sub-portions and a thickness of the collimating lens satisfy the following formula:
$${D}_{1} \times tan {θ}_{1} = {K}_{1} \times ( {D}_{1} \times tan {θ}_{2} + {D}_{2} \times tan {θ}_{3} ) ;$$
wherein D₁ represents the optical path between the light-emitting chip and the first collimating sub-portion; D₂ represents the thickness of the collimating lens; θ₁ represents a divergence angle of the laser beam emitted by the light-emitting chip in the fast axis direction; θ₂ represents a divergence angle of the laser beam emitted by the light-emitting chip in the slow axis direction; θ₃ represents a refraction angle of the laser beam emitted by the light-emitting chip after passing through the first collimating sub-portion; K₁ represents a first coefficient, the first coefficient is equal to a ratio of a dimension of a beam spot formed by the laser beam after passing through the second collimating portion in the fast axis direction to a dimension of the beam spot in the slow axis direction, and the first coefficient is greater than or equal to 0.2 and less than or equal to 5.0.

5. The light-emitting device according to claim 4, wherein D₁ is greater than or equal to 2 mm and less than or equal to 20 mm, and D₂ is greater than or equal to 2 mm and less than or equal to 20 mm.

6. The light-emitting device according to claim 4, wherein the plurality of light-emitting chips include: a first light-emitting chip, a second light-emitting chip, and a third light-emitting chip; a number of first light-emitting chips is greater than a number of second light-emitting chips and a number of third light-emitting chips; the first light-emitting chip is configured to emit a red laser beam; one of the second light-emitting chip and the third light-emitting chip is configured to emit a blue laser beam, and another of the second light-emitting chip and the third light-emitting chip is configured to emit a green laser beam;
an optical path between the first light-emitting chip and a corresponding first collimating sub-portion and the thickness of the collimating lens satisfy at least one of:
$${D}_{11} \times tan {θ}_{1} = {K}_{2} \times ( {D}_{11} \times tan {θ}_{2} + {D}_{2} \times tan {θ}_{3} ) ; or$$
$${D}_{11} \times tan {θ}_{1} = {K}_{3} \times ( {D}_{11} \times tan {θ}_{2} + {D}_{2} \times tan {θ}_{3} ) ;$$
wherein D₁₁ represents the optical path between the first light-emitting chip and the corresponding first collimating sub-portion, K₂ represents a second coefficient, and the second coefficient is greater than 1.0 and less than or equal to 5.0; K₃ represents a third coefficient, and the third coefficient is greater than 0.2 and less than or equal to 1.0; the first coefficient includes the second coefficient and the third coefficient.

7. The light-emitting device according to claim 2, wherein in the first direction, a width of any one of the plurality of first collimating sub-portions is greater than or equal to 1 mm and less than or equal to 20 mm; and
in the second direction, a width of any one of the plurality of second collimating sub-portions is greater than or equal to 1 mm and less than or equal to 20 mm.

8. The light-emitting device according to claim 2, wherein a radius of curvature of any one of the plurality of first collimating sub-portions is greater than or equal to 2 mm and less than or equal to 20 mm; a radius of curvature of any one of the plurality of second collimating sub-portions is greater than or equal to 2 mm and less than or equal to 20 mm; and the radius of curvature of the first collimating sub-portion is less than the radius of curvature of the second collimating sub-portion.

9. The light-emitting device according to claim 1, wherein the collimating lens includes:
a first region, configured to collimate a laser beam incident on the first region;
a second region, located on at least one side of the first region in the first direction; and
a beam path adjusting component, located in the second region, the beam path adjusting component being configured to adjust a beam path of a laser beam incident on the second region, such that the adjusted laser beam is incident on the first region.

10. The light-emitting device according to claim 9, wherein the collimating lens further includes a groove, a side of the collimating lens facing the plurality of light-emitting chips is recessed in a direction away from the plurality of light-emitting chips, to form the groove, and the groove includes:
a bottom surface, the bottom surface being a laser-incident surface of the collimating lens and being located in the first region; and
a side wall, the side wall serving as a first adjusting sub-component, wherein the first adjusting sub-component is located in the second region and is configured to: adjust the beam path of the laser beam incident on the second region, such that the laser beam incident on the second region is incident on the first region, the beam path adjusting component includes the first adjusting sub-component.

11. The light-emitting device according to claim 10, wherein the first adjusting sub-component satisfies at least one of the following:
a first angle between the first adjusting sub-component and the laser-incident surface is greater than or equal to 110° and less than or equal to 140°; or
in a thickness direction of the collimating lens, a depth of the groove is greater than or equal to 0.5 mm and less than or equal to 0.7 mm.

12. The light-emitting device according to claim 10, wherein the collimating lens further includes a target curved surface, the target curved surface is a surface of the collimating lens away from the laser-incident surface and located in the first region, the target curved surface protrudes in a direction away from the laser-incident surface; a thickness of the target curved surface is greater than or equal to 0.8 mm and less than or equal to 1.1 mm; and a thickness of the collimating lens is greater than or equal to 1.5 mm and less than or equal to 2.5 mm.

13. The light-emitting device according to claim 9, wherein the beam path adjusting component includes a second adjusting sub-component; the second adjusting sub-component includes two side walls of the collimating lens in the first direction; the second adjusting sub-component is configured to: adjust the beam path of the laser beam incident on the second region, such that the laser beam incident on the second region is incident on the first region; the collimating lens further includes a laser-incident surface, the laser-incident surface is a surface of the collimating lens facing the plurality of light-emitting chips and located in the first region and the second region.

14. The light-emitting device according to claim 13, wherein a second angle between the second adjusting sub-component and the laser-incident surface is greater than or equal to 40° and less than or equal to 50°.

15. The light-emitting device according to claim 13, wherein the collimating lens further includes a target curved surface, the target curved surface is a surface of the collimating lens away from the laser-incident surface and located in the first region, the target curved surface protrudes in a direction away from the laser-incident surface; a thickness of the target curved surface is greater than or equal to 0.8 mm and less than or equal to 1.1 mm; in a thickness direction of the collimating lens, a minimum distance between the target curved surface and the laser-incident surface is greater than or equal to 0.7 mm and less than or equal to 0.9 mm.

16. The light-emitting device according to claim 9, wherein a thickness of the collimating lens is greater than or equal to 1.5 mm and less than or equal to 2.0 mm; an optical path between any one of the plurality of light-emitting chips and a laser-incident surface of the collimating lens is greater than or equal to 1.9 mm and less than or equal to 2.2 mm; and a width of the first region in the first direction is greater than or equal to 3.0 mm and less than or equal to 3.4 mm.

17. The light-emitting device according to claim 9, wherein the collimating lens further includes a microstructure surface, the microstructure surface includes a portion of a surface of the collimating lens away from the plurality of light-emitting chips and is located in the second region, the microstructure surface is configured to collimate a laser beam incident on the microstructure surface; the microstructure surface includes at least one of a Fresnel structure surface or a diffractive optical element.

18. A projection apparatus, comprising:
a laser source assembly, configured to emit illumination beams, the laser source assembly including the light-emitting device according to claim 1;
a light modulation assembly, configured to modulate the illumination beams emitted by the laser source assembly, so as to obtain projection beams; and
a projection lens, configured to project the projection beams into an image.

19. A light-emitting device, comprising:
a plurality of light-emitting chips, arranged in an array along a first direction and a second direction, the plurality of light-emitting chips being configured to emit laser beams in the first direction; and
a collimating lens, disposed on laser-exit sides of the plurality of light-emitting chips, the collimating lens being configured to collimate the incident laser beams and including:
a first collimating portion, the first collimating portion being a surface of the collimating lens facing the plurality of light-emitting chips, the first collimating portion being configured to: collimate an incident laser beam in a third direction and reduce a divergence angle of the incident laser beam in the second direction, such that a divergence angle of a laser beam exiting from the first collimating portion in the third direction is reduced to 0°, a divergence angle of the laser beam exiting from the first collimating portion in the second direction is reduced, and the divergence angle of the laser beam exiting from the first collimating portion in the second direction is greater than 0°; wherein a divergence angle of the laser beam incident on the first collimating portion in the third direction is greater than a divergence angle of the laser beam incident on the first collimating portion in the second direction, the second direction is parallel to a slow axis direction of the laser beam incident on the first collimating portion, the third direction is parallel to a fast axis direction of the laser beam incident on the first collimating portion, the first direction, the second direction, and the third direction are perpendicular to each other; and
a second collimating portion, the second collimating portion being a surface of the collimating lens away from the plurality of light-emitting chips, the second collimating portion and the first collimating portion being arranged at an interval, and the second collimating portion being configured to: collimate an incident laser beam in the second direction, such that a divergence angle of a laser beam exiting from the second collimating portion in the third direction remains unchanged, and a divergence angle of the laser beam exiting from the second collimating portion in the second direction is reduced to 0°;
wherein a change amount between a divergence angle of the laser beam incident on the second collimating portion in the second direction and the divergence angle of the laser beam exiting from the second collimating portion in the second direction is greater than a change amount between the divergence angle of the laser beam incident on the first collimating portion in the second direction and the divergence angle of the laser beam exiting from the first collimating portion in the second direction; and
the first collimating portion includes a first collimating sub-portion, and the first collimating sub-portion extends along the second direction; and the second collimating portion includes a plurality of second collimating sub-portions; the plurality of second collimating sub-portions are arranged along the second direction, each of the plurality of second collimating sub-portions extends along the third direction.

20. A light-emitting device, comprising:
a plurality of light-emitting chips, configured to emit laser beams; and
a collimating lens, located on laser-exit sides of the plurality of light-emitting chips, the collimating lens being configured to receive the laser beams from the plurality of light-emitting chips and collimate the incident laser beams, and the collimating lens including:
a first region, configured to collimate a laser beam incident on the first region;
a second region, located on at least one side of the first region in at least one of a first direction or a second direction, wherein the first direction and the second direction each are perpendicular to a thickness direction of the collimating lens; and
a beam path adjusting component, located in the second region and configured to adjust a beam path of a laser beam incident on the second region, such that the adjusted laser beam is incident on the first region.
